(19) United States
(12) Patent Application Publication
(10) Pub. No.: US 2010/0237499 A1
(43) Pub. Date: Sep. 23, 2010

(54) SEMICONDUCTOR DEVICE, AND STACKED STRUCTURE, PACKAGE, MODULE, AND ELECTRONIC APPARATUS INCLUDING THE SAME, AND METHOD OF FABRICATING THE SAME

(75) Inventor: Hee-Jeong KIM, Seoul (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 12/709,684

(22) Filed: Feb. 22, 2010

(30) Foreign Application Priority Data
Feb. 25, 2009 (KR) 2009-0015958

(51) Int. Cl. H01L 23/48; H01L 23/488

(52) U.S. Cl. 257/741; 257/774; 257/779; 257/784; 257/E23.011; 257/E23.023

(57) ABSTRACT

Semiconductor devices, as well as stacked structures, packages, modules, and electronic apparatus including the semiconductor device, and methods of fabricating the same. The semiconductor device includes a circuit layer on a substrate, a metal interconnection layer on the circuit layer, the metal interconnection layer having a copper interconnection and a protection layer, a first and a second through silicon via plugs vertically penetrating the circuit layer, a first via pad on the first through silicon via plug, and a second via pad on the second through silicon via plug, wherein the first via pad is electrically connected to the copper interconnection, and wherein the second via pad is electrically insulated from the copper interconnection.

### CROSS-REFERENCE TO RELATED APPLICATIONS

This application claims priority under 35 U.S.C. §119 from Korean Patent Application No. 10-2009-0015958, filed on Feb. 25, 2009, the contents of which are incorporated herein by reference in their entirety.

### BACKGROUND

1. Field of the Invention

Example embodiments of the present general inventive concept relate to a semiconductor device, as well as stacked structures, packages, modules, and electronic apparatus including the semiconductor device, and methods of fabricating the same.

2. Description of the Related Art

In a semiconductor device requiring a high operating speed, copper is selected as a conductor that exhibits high conductivity and low resistance. However, copper is not formed and patterned using a deposition technique and an etching technique, which have typically been used to form a conventional a semiconductor device.

### SUMMARY

Example embodiments of the present general inventive concept provide semiconductor devices.

Example embodiments of the present general inventive concept provide stacked structures including the semiconductor devices.

Example embodiments of the present general inventive concept provide semiconductor packages including the semiconductor devices.

Example embodiments of the present general inventive concept provide a semiconductor module including the semiconductor devices.

Example embodiments of the present general inventive concept provide an electronic apparatus including the semiconductor devices.

Example embodiments of the present general inventive concept provide methods of fabricating the semiconductor devices.

The example embodiments are not limited to the above mentioned embodiments, and other example embodiments may be obviously understood to one of ordinary skill in the art from the following disclosure.

Example embodiments of the present general inventive concept provide a semiconductor device includes a circuit layer on a substrate, a metal interconnection layer on the circuit layer, the metal interconnection layer having a copper interconnection and a protection layer, a first and a second through silicon via plugs vertically penetrating the circuit layer, a first via pad on the first through silicon via plug, and a second via pad on the second through silicon via plug, where the first via pad is electrically connected to the copper interconnection, and where the second via pad is electrically insulated from the copper interconnection.

Example embodiments of the present general inventive concept also provide a semiconductor device includes a substrate having a first region and a second region, a first circuit layer at the first region, a first metal interconnection layer on the first circuit layer, the first metal interconnection having a first copper interconnection and a first protection layer, a first through silicon via plug vertically penetrating the first circuit layer, a first via pad on the first through silicon via plug, the first via pad being formed of copper, and a first redistribution structure on the first via pad, the first redistribution structure including gold, and wherein the first via pad and the first metal interconnection are electrically connected to each other and transferring a voltage, and a second circuit layer at the second region, a second metal interconnection layer on the second circuit layer, the second metal interconnection having a second copper interconnection and a second protection layer, a second through silicon via plug vertically penetrating the second circuit layer, a second via pad on the second through silicon via plug, the second via pad being formed of copper, and a second redistribution structure on the second via pad, the second redistribution structure including gold, and where the second via pad and the second metal interconnection are electrically insulated from each other, and where the second via pad transfers a chip select signal.

Example embodiments of the present general inventive concept also provide a semiconductor stacked structure includes an upper semiconductor device and a lower semiconductor device, each semiconductor device including a circuit layer on a substrate, a metal interconnection layer on the circuit layer, the metal interconnection layer having a copper interconnection and a protection layer, a first and a second through silicon via plugs vertically penetrating the circuit layer, a first via pad on the first through silicon via plug, and a second via pad on the second through silicon via plug, where the first via pad is electrically connected to the copper interconnection, and where the second via pad is electrically insulated from the copper interconnection, and where any one of the through silicon via plugs of the upper semiconductor device is electrically connected to any one of the through silicon via plugs of the lower semiconductor device.

Example embodiments of the present general inventive concept also provide a semiconductor package includes a package substrate having a wire pad, a semiconductor device disposed on the package substrate, the semiconductor device having a bonding pad, and a wire to electrically connect the wire pad to the bonding pad, wherein the semiconductor device comprises a circuit layer on a substrate, a metal interconnection layer on the circuit layer, the metal interconnection layer having a copper interconnection and a protection layer, a first and a second through silicon via plugs vertically penetrating the circuit layer, a first via pad on the first through silicon via plug, and a second via pad on the second through silicon via plug, wherein the first via pad is electrically connected to the copper interconnection, and where the second via pad is electrically insulated from the copper interconnection.

Example embodiments of the present general inventive concept also provide a semiconductor package includes a package substrate having a solder land, a semiconductor device disposed on the package substrate, the semiconductor device having a solder pad, and a connector to electrically connect the solder land to the solder pad, wherein the semiconductor device comprises, a circuit layer on a substrate, a metal interconnection layer on the circuit layer, the metal interconnection layer having a copper interconnection and a protection layer, a first and a second through silicon via plugs vertically penetrating the circuit layer, a first via pad on the first through silicon via plug, and a second via pad on the second through silicon via plug, where the first via pad is electrically connected to the copper interconnection, and where the second via pad is electrically insulated from the copper interconnection, and where the solder pad is electrically connected to the first through silicon via plug.

Example embodiments of the present general inventive concept also provide a semiconductor module includes a module substrate, a plurality of semiconductor devices disposed on the module substrate, and a plurality of contact terminals disposed at edge of the module substrate and connected to the plurality of the semiconductor devices, respectively, wherein at least one of the plurality of the semiconductor devices comprises, a circuit layer on a substrate, a metal interconnection layer on the circuit layer, the metal interconnection layer having a copper interconnection and a protection layer, a first and a second through silicon via plugs vertically penetrating the circuit layer, a first via pad on the first through silicon via plug, and a second via pad on the second through silicon via plug, where the first via pad is electrically connected to the copper interconnection, and where the second via pad is electrically insulated from the copper interconnection.

Example embodiments of the present general inventive concept also provide an electronic apparatus includes a housing, a memory unit having a semiconductor device, a controller, and an input/output unit, where the semiconductor device includes a circuit layer on a substrate, a metal interconnection layer on the circuit layer, the metal interconnection layer having a copper interconnection and a protection layer, a first and a second through silicon via plugs vertically penetrating the circuit layer, a first via pad on the first through silicon via plug, and a second via pad on the second through silicon via plug, where the first via pad is electrically connected to the copper interconnection, and where the second via pad is electrically insulated from the copper interconnection.

Example embodiments of the present general inventive concept also provide a method of fabricating a semiconductor device includes preparing a substrate, the method including forming a circuit layer on the substrate, forming a metal interconnection layer on the circuit layer, the metal interconnection layer having a copper interconnection and a protection layer, forming a first and a second through silicon via plugs vertically penetrating the circuit layer, forming a first via pad on the first through silicon via plug, and forming a second via pad on the second through silicon via plug, where the first via pad is electrically connected to the copper interconnection, and where the second via pad is electrically insulated from the copper interconnection.

Example embodiments of the present general inventive concept also provide a semiconductor package, including a package substrate having a wire pad, a semiconductor device disposed on the package substrate, the semiconductor device having a bonding pad, a metal interconnection layer on a circuit layer having a copper interconnection and a protection layer, and first and second via pads, and a wire to electrically connect the wire pad to the bonding pad, where the first via pad is electrically connected to the copper interconnection, and the second via pad is electrically insulated from the copper interconnection.

Example embodiments of the present general inventive concept also provide a method of forming a semiconductor package, the method including forming a package substrate having a wire pad, disposing a semiconductor device on the package substrate, the semiconductor device having a bonding pad, a metal interconnection layer on a circuit layer having a copper interconnection and a protection layer, and first and second via pads, electrically connecting the first via pad to the copper interconnection, electrically insulating the second via pad from the copper interconnection, and electrically connecting the wire pad to the bonding pad with a wire.

Example embodiments of the present general inventive concept also provide a semiconductor module, including a module substrate, a plurality of semiconductor devices disposed on the module substrate, where at least one of the plurality of semiconductor devices includes a bonding pad, a metal interconnection layer on a circuit layer having a copper interconnection and a protection layer, and first and second via pads, and a plurality of contact terminals disposed at an edge of the module substrate and connected to the plurality of the semiconductor devices, respectively, where the first via pad is electrically connected to the copper interconnection, and the second via pad is electrically insulated from the copper interconnection.

Example embodiments of the present general inventive concept also provide a method of forming a semiconductor module, the method including forming a module substrate, disposing a plurality of semiconductor devices on the module substrate, where at least one of the plurality of semiconductor devices includes a bonding pad, a metal interconnection layer on a circuit layer having a copper interconnection and a protection layer, and first and second via pads, electrically connecting the first via pad to the copper interconnection, electrically insulating the second via pad from the copper interconnection, and disposing a plurality of contact terminals at an edge of the module substrate and connecting the plurality of contact terminals to the plurality of the semiconductor devices, respectively.

### BRIEF DESCRIPTION OF THE DRAWINGS

The above and/or other features and utilities of the present general inventive concept will become apparent and more readily appreciated from the following description of the exemplary embodiments, taken in conjunction with the accompanying drawings, in which:

FIGS. 1A, 2A, 3A, and 4A are schematic cross-sectional views illustrating a semiconductor device according to various example embodiments of the present general inventive concept;

FIGS. 1B, 2B, 3B, and 4B are schematic cross-sectional views illustrating a semiconductor device according to various example embodiments of the present general inventive concept;

FIG. 5 is a schematic cross-sectional view illustrating a stacked structure of a semiconductor device according to exemplary embodiments of the present general inventive concept;

FIGS. 6A to 6G are schematic cross-sectional views illustrating a method of fabricating a semiconductor device according to exemplary embodiments of the present general inventive concept;

FIGS. 7A to 7H are schematic cross-sectional views illustrating a method of fabricating a semiconductor device according to exemplary embodiments of the present general inventive concept;

FIGS. 8A to 8G are schematic cross-sectional views illustrating a method of fabricating a semiconductor device according to example embodiments of the present general inventive concept;

FIGS. 9A to 9G are schematic cross-sectional views illustrating a method of fabricating a semiconductor device according to example embodiments of the general inventive concept;

FIG. 10 illustrates a laser beam that is irradiated by a laser to cut at least a portion of a semiconductor device according to example embodiments of the present general inventive concept;

FIGS. 11A and 11B are schematic cross-sectional views illustrating semiconductor packages including a semiconductor device according to example embodiments of the present general inventive concept;

FIGS. 12A and 12B are schematic cross-sectional views illustrating semiconductor packages including a semiconductor device according to example embodiments of the present general inventive concept;

FIG. 13 is a plan view illustrating a semiconductor module including a semiconductor device according to example embodiments of the present general inventive concept; and

FIG. 14 is a block diagram illustrating an electronic apparatus including a semiconductor device according to example embodiments of the present general inventive concept.

### DETAILED DESCRIPTION OF THE EMBODIMENTS

Various example embodiments of the present general inventive concept will now be described more fully with reference to the accompanying drawings in which example embodiments are illustrated, wherein like reference numerals refer to the like elements throughout. This present general inventive concept may, however, be embodied in different forms and should not be construed as limited to the embodiments set forth herein. Rather, these embodiments are provided so that this disclosure is thorough and complete and fully conveys the scope of the inventive concept to one skilled in the art. The sizes of a layer and regions may be exaggerated for clarity. Like reference numerals designate like elements throughout the specification.

It will be understood that interconnections are used to describe a conductor transmitting an electrical signal in a horizontal direction, and vias are used to describe a conductor transmitting an electrical signal in a vertical direction. That is, regardless of the shape illustrated in the drawing, the interconnections may be longitudinally formed in a horizontal direction, and the vias may be longitudinally formed in a vertical direction. The vias include plugs and holes. The via plug denotes a columnar conductor filling the via hole, and the via hole denotes a hollow structure to be filled with the via plug. A contact pad may be distinguished from a redistribution structure in terms of functional difference. That is, they may be elements having the same shape and structure. In other words, the contact pad may be a portion of the redistribution structure.

When conductive patterns are formed of copper or formed by plating, it is regarded that a seed layer is formed, and then a plating process is performed. That is, forming the conductive patterns using copper or plating may be understood that forming a seed layer precedes a process such as chemical mechanical polishing (CMP). Copper may be formed by plating, and a CMP method may be used to pattern copper. Although copper as utilized in the present general inventive concept may be formed by plating with a CMP method, if other conductive metals are selected, they may be formed by deposition and etching.

In the below description and/or in the accompanying drawings, if a barrier metal film is not illustrated in the drawing or is not described, it may be omitted for the sake of simplicity. That is, in describing exemplary embodiments of the present general inventive concept, the formation of the barrier metal film may be omitted from the description and drawings for the sake of simplicity. In particular, when copper is used, the barrier metal film may be formed. Therefore, although the barrier metal film is not described, it will be understood that the barrier metal film may be formed between copper and other materials.

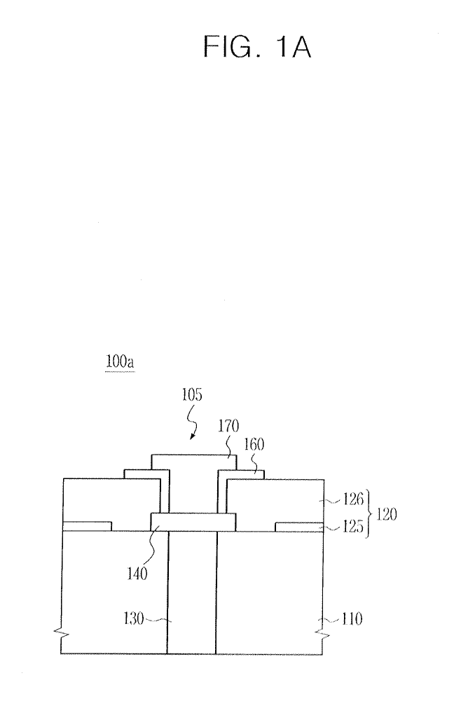

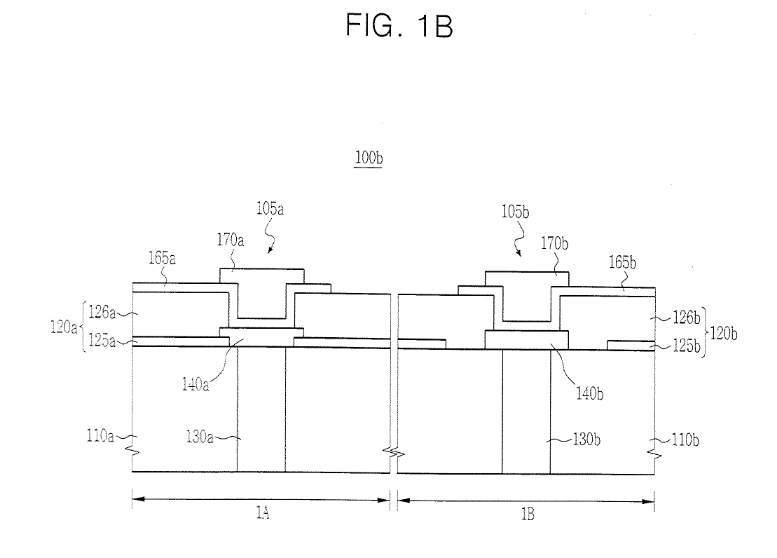

FIG. 1A is a cross-sectional view illustrating a semiconductor device including a copper pad according to example embodiments of the present general inventive concept. Referring to FIG. 1A, a semiconductor device 100a can include a circuitry layer 110, a metal interconnection layer 120, and an input/output part (IO part) 105 including a through silicon via plug (TSVP) 130.

The circuitry layer 110 can be a region including semiconductor circuits to perform one or more electrical operations. The semiconductor circuit may be formed on a semiconductor substrate including silicon using conductors including polysilicon, metal silicide, and/or a metal, and insulators including silicon oxide, silicon nitride, etc. The circuitry layer 110 may include a copper interconnection. The TSVP 130 may penetrate the circuitry layer 110. One of the substrates for the one or more semiconductor devices may include a silicon substrate, a silicon germanium substrate, a compound semiconductor substrate and a SOI (silicon-on-insulator) substrate may be used as the semiconductor substrate.

The metal interconnection layer 120 can include a multilayer structure of metal interconnections 125 and a protection layer 126. The metal interconnection layer 120 may include an interconnection formed of copper. Each of the metal interconnections 125 may transmit an electrical signal to the circuitry layer 110 from the outside or to the outside from the circuitry layer 110. Although the metal interconnections 125 are illustrated in a rectangular island shape, the metal interconnections 125 may be longitudinally formed forward and backward or left and right. The illustrated metal interconnections 125 may be uppermost metal interconnections disposed on an uppermost layer. It may be understood that only single-layer metal interconnections 125 are illustrated in FIG. 1A for the sake of clarity. Also, the TSVP 130 may penetrate the metal interconnection layer 120.

The protection layer 126 may be formed in a multilayer structure using an insulating material such as silicon oxide, silicon nitride, silicon oxynitride, or various polyimides. In the drawing of FIG. 1A, for the sake of clarity, it is illustrated that the protection layer 126 is formed in a single layer structure.

The IO part 105 may include the TSVP 130, a via pad 140, a contact pad 160 and an input and output pin (“IO pin”) 170. While the reference IO pin 170 may denote a pin exposed to the outside of semiconductor devices, it may be understood that it can denote a part electrically connected to a pin exposed to the outside of a semiconductor device.

The TSVP 130 may be formed to vertically penetrate the circuitry layer 110 and the metal interconnection layer 120. The TSVP 130 may include a via plug and a via hole. In the drawing, the TSVPs 130 may include the via plugs and the via holes. The via plug 130 may be formed of a metal, e.g., copper. A barrier metal film (not illustrated) may be formed at the interface between the TSVP 130 and the circuitry layer 110. The barrier metal film may be formed of Ti/TiN or TaN.

The via pad 140 may be formed in a mesa shape (e.g., rectangular). The via pad 140 may be formed of copper. A barrier metal film (not illustrated) may be formed between the via pad 140 and the TSVP 130. When the via pad 140 is formed of copper, a barrier metal film may not be formed between the TSVP 130 and the via pad 140. When the via pad 140 is formed of a metal, e.g., aluminum, tungsten or other metals rather than copper, a barrier metal film may be formed.

In order to generalize the formation of the semiconductor device 100a for the sake of clarity, the barrier metal film is not illustrated. According to the present general inventive concept, after the TSVP 130 is formed, the barrier metal film is formed on a surface of the TSVP 130. A process of forming the TSVP 130 may be completed on one or more locations. For example, although a top surface of the TSVP 130 may be formed at the same level as a top surface of the circuitry layer 110 (i.e., a lower surface of the metal interconnection layer 120), it is not required. When the process of forming the TSVP 130 is performed in excess of the desired process, the top surface of the TSVP 130 may be formed on a middle level of the via pad 140. Also, the top surface of the TSVP 130 may be formed at the same level as the top surface of the illustrated via pad 140. This is because the TSVP 130 may be formed by a plating process.

A contact pad 160 may be a conductor formed between the protection layer 126 and the pin 170. The contact pad 160 may be in contact with the top surface of the via pad 140 and extend toward the top surface of the protection layer 126. Moreover, the contact pad 160 may be a conductor formed between the via pad 140 and the IO pin 170. Although FIG. 1A illustrates that the contact pad 160 is not formed between the via pad 140 and the IO pin 170 in the drawing, the contact pad 160 may be formed on at least a portion of and/or the entire surface of the via pad 140. That is, the contact pad 160 may be formed between the via pad 140 and the pin 170. Such application example embodiments may be understood with reference to the attached other drawings and the descriptions thereof. In exemplary embodiments of the present general inventive concept, barrier metal film (not illustrated) may be formed between the contact pad 160 and the via pad 140, or between the contact pad 160 and the IO pin 170. That is, when the contact pad 160 and the via pad 140 or the contact pad 160 and the IO pin 170 are formed of different metals or one of them is formed of copper, the barrier metal film may be formed therebetween. Alternatively, the contact pad 160 may be formed as a barrier metal film. For example, the contact pad 160 may be a barrier metal film. In exemplary embodiments of the present general inventive concept, the contact pad 160 may be a part or another name of a redistribution structure.

The IO pin 170 may be formed on an uppermost part of the semiconductor device 100a to be electrically connected to another semiconductor device or module. The IO pin 170 may be formed of copper, aluminum, tungsten, nickel, gold, silver and other conductive metals. Another barrier metal film may be formed on the IO pin 170. The IO pin 170 may be electrically connected to an IO pin of another semiconductor device.

FIG. 1B is a cross-sectional view illustrating a semiconductor device according to example embodiments of the present general inventive concept. Referring to FIG. 1B, a semiconductor device 100b according to example embodiments of the present general inventive concept includes two regions, i.e., a first region 1A and a second region 1B. The regions include a first and a second circuitry layers 110a and 110b, protective layers 126a and 126b, a first and a second metal interconnection layers 120a and 120b, a first and a second IO parts 105a and 105b including a first and a second TSVPs 130a and 130b, respectively. The schematic descriptions of the circuitry layers 110a and 110b, the metal interconnection layers 120a and 120b, the TSVPs 130a and 130b and the IO parts 105a and 105b will be omitted, and the elements may be schematically understood with reference to FIG. 1A and the description thereof.

The IO parts 105a and 105b include the TSVPs 130a and 130b, via pads 140a and 140b, redistribution structures 165a and 165b, and IO pins 170a and 170b, respectively. Some portions of the redistribution structures 165a and 165b may function as contact pads, and may form interconnection structures to electrically connect the IO parts 105a and 105b to other IO parts disposed on other locations. A case in which the redistribution structures 165a and 165b function as contact pads will be understood with reference to FIG. 1A and the description thereof.

The via pad 140a of the region 1A may be electrically connected to the metal interconnection 125a of the metal interconnection layer 120a, and the via pad 140b of the region 1B may be electrically insulated from the metal interconnection 125b of the metal interconnection layer 120b. The metal interconnection 125a of the region 1A may be formed to be electrically or physically connected to the via pad 140a, and the metal interconnection 125b of the region 1B may be formed not to be electrically or physically connected to the via pad 140b. In other words, the metal interconnection 125b of the region 1B may be spaced apart from the via pad 140b, with, for example, protection layer 126b. The IO part 105a of the region 1A may operate the semiconductor device 100a or transmit a data or voltage signal required during an operation. The IO part 105b of the region 1B may transmit a chip select signal selecting the semiconductor device 100a. The metal interconnections 125a and 125b may be formed at the same level. The via pads 140a and 140b may be formed at the same level as well. The metal interconnections 125a and 125b may be formed at the same level as the via pads 140a and 140b. The metal interconnections 125a and 125b and the via pads 140a and 140b may be formed into the same or similar thickness. The redistribution structures 165a and 165b and IO pins 170a and 170b may be formed at the same or similar level or the same top surface.

In example embodiments of the present general inventive concept, top surfaces of the TSVP 130a and 130b may be formed at a middle level of the via pads 140a and 140b, or the same or similar level as top surfaces of the via pads 140a and 140b.

According to exemplary embodiments of the present general inventive concept, electrical signals, e.g., data signals or voltage signals, for operations of a semiconductor device may be transmitted to a metal interconnection through a TSVP. A chip select signal may be insulated from the metal interconnection. When signals are insulated from the metal interconnection, the semiconductor device may not operate, and thus the metal interconnections may be electrically connected to each other. The chip select signal may be transmitted to select a semiconductor device, and thus may be insulated from the metal interconnection. In particular, when unit semiconductor chips are stacked to form a multi-stacked semiconductor device in order to increase a process capacity, the chip select signal can transmit an electrical signal to one of the stacked unit semiconductor chips. Therefore, the through silicon via transmitting a chip select signal can be insulated from the metal interconnection, and thus may be implemented through various example embodiments. For example, the first IO part 105a including as the first TSVP 130a and the first via pad 140a, the first redistribution structure 165a, and the first metal interconnection 125a may transfer commonly applying electric signals for semiconductor operation such as a supply voltage, ground voltage, clock signals, or data signals. According to the present general inventive concept, the second IO part 105b including the second TSVP 130b and the second via pad 140b, and the second redistribution structure 165b may transfer exclusive electric signals such as a chip select signal. Because exclusive signals may not apply to every semiconductor device, TSVPs or via pads transferring the exclusive signals may be isolated from metal interconnections in one or more semiconductor devices.

The redistribution structures 165a and 165b may electrically connect the IO parts 105a and 105b to other IO parts disposed on other locations (e.g., other locations in the semiconductor device 100b). However, the redistribution structures 165a and 165b are not necessarily formed to electrically connect the IO parts to other IO parts on other locations. The redistribution structures 165a and 165b may include an interconnection structure and a via structure. It will be understood that the redistribution structures 165a and 165b may include an interconnection structure and a via structure. For example, the contact pad 160 of FIG. 1A and the redistribution structure 165a and 165b may be understood as via structures and/or interconnection structures. It will be easily understood that a part of the redistribution structures 165a and 165b may have via structures with reference to the drawings attached to the specification.

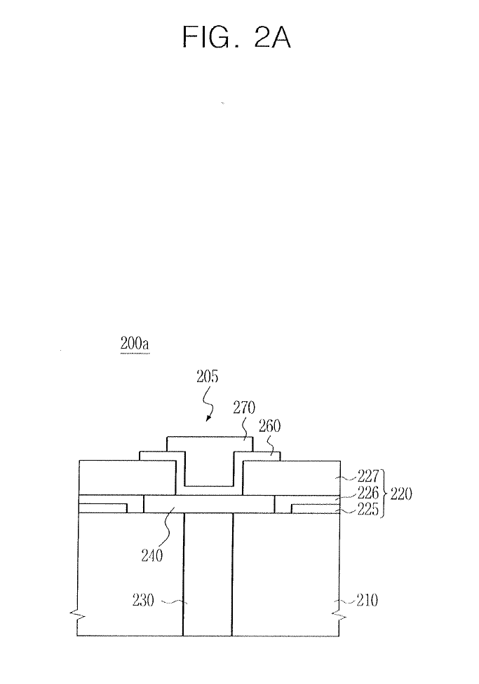

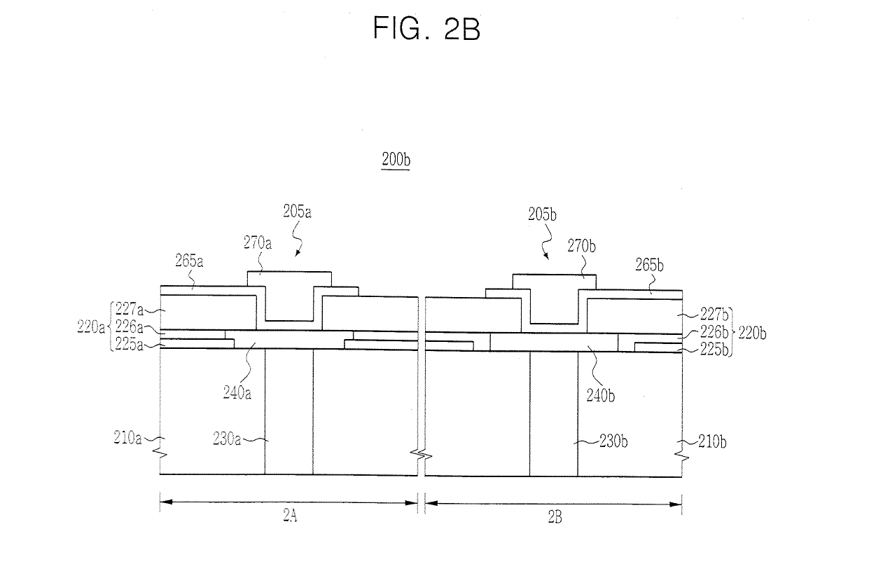

FIG. 2A is a cross-sectional view of a semiconductor device including a copper pad according to example embodiments of the present general inventive concept. Referring to FIG. 2A, a semiconductor device 200a according to example embodiments of the present general inventive concept includes a circuitry layer 210, a metal interconnection layer 220, and an input/output part (IO part) 205 including a through silicon via plug (TSVP) 230.

The schematic descriptions of the circuitry layer 210, the metal interconnection layer 220, the TSVP 230 and the IO part 205 will be omitted, and they will be schematically understood with reference to FIGS. 1A and 1B and the descriptions thereof.

In the semiconductor device 200a according to the present example embodiment, a top surface of a TSVP 230 may be formed at a higher level than a lower surface of a via pad 240. Alternatively, the lower surface of the via pad 240 may be formed at a lower level than the top surface of metal interconnections 225. Also, the top surface of the TSVP 230 may be formed at a higher level than the top surface of the circuitry layer 210. The TSVP 230 and/or the via pad 240 may be formed electrically or physically insulated from the metal interconnections 225.

In example embodiments of the present general inventive concept, the metal interconnection layer 220 may include a lower protection layer 226 and an upper protection layer 227. The lower protection layer 226 may be formed to entirely cover the metal interconnections 225. A top surface of the lower protection layer 226 may be formed at similar or the same level as the via pad 240. The upper protection layer 227 may be formed on the lower protection layer 226 and the via pad 240. The lower protection layer 226 and the upper protection layer 227 may be formed of at least one of a silicon oxide layer, a silicon nitride layer, a silicon oxynitride layer and various polyimides. Particularly, the lower protection layer 226 may be a silicon nitride layer and the upper protection layer may be a polyimide.

In example embodiments of the present general inventive concept, the contact pad 260 is illustrated to be completely covered so that the IO pin 270 is not in physical contact with other elements. This is illustrated to describe that the shape is compatible with that illustrated in FIG. 1A.

FIG. 2B is a cross-sectional view illustrating a semiconductor device according to example embodiments of the present general inventive concept. Referring to FIG. 2B, a semiconductor device 200b according to example embodiments of the present general inventive concept includes two regions, i.e., a first region 2A and a second region 2B. The regions include a first and a second circuitry layers 210a and 210b, a first and a second metal interconnection layers 220a and 220b, a first and a second IO pins 205a and 205b including a first and a second TSVPs 230a and 230b, respectively. The schematic descriptions of the circuitry layers 210a and 210b, the metal interconnection layers 220a and 220b, the TSVPs 230a and 230b and the IO parts 205a and 205b will be omitted, and the elements will be schematically understood with reference to FIGS. 1A to 2A and the description thereof. In particular, the semiconductor device 200b according to the example embodiments of the present general inventive concept may be understood with reference to the semiconductor device 200a illustrated in FIG. 2A. Lower protection layers 226a and 226b illustrated in FIG. 2B may be similar or the same as lower metal protection layer 226 as illustrated in FIG. 2A and described above, and upper protection layers 227a and 227b illustrated in FIG. 2B may be similar or the same as lower metal protection layer 227 as illustrated in FIG. 2A and described above.

In the example embodiment illustrated in FIG. 2B, the IO parts 205a and 205b may include the TSVPs 230a, 230b, via pads 240a and 240b, redistribution structures 265a and 265b, and IO pins 270a and 270b. Each of the redistribution structures 265a and 265b may function as a contact pad, and may be formed in an interconnection structure to electrically connect the IO parts 205a and 205b to other IO parts disposed on other locations (e.g., other locations of the semiconductor device 200b). The redistribution structures 265a and 265b may function as contact pads, as will be understood with reference to FIGS. 1A and 2A and the descriptions thereof.

The TSVPs 230a and 230b may be formed at a higher level than bottom surfaces of the via pads 240a and 240b. Also, the bottom surfaces of the via pads 240a and 240b may be formed at a lower level than top surface of the metal interconnections 225a and 225b. In exemplary embodiments of the present general inventive concept, the TSVP 230b and/or the via pad 240b of the region 2B may be formed so as not to be electrically or physically connected to the metal interconnections 225b.

The metal interconnections 225a of the region 2A may be electrically or physically connected to the via pad 240a, and the metal interconnections 225a of the region 2B may be formed so as not to be electrically or physically connected to the via pad 240a. That is, the metal interconnections 225a of the region 2B may be spaced apart from the via pad 240a. The TSVP 230a of the region 2A may be electrically connected to the metal interconnection 225a of the metal interconnection layer 220a, and the TSVP 230b of the region 2B may be electrically insulated from the metal interconnections 225b of the metal interconnection layer 220b. The IO part 205a of the region 2A may operate the semiconductor device 200b or transmit a data or voltage signal required during an operation. The IO part 205a of the region 2B may transmit a chip select signal selecting the semiconductor device 200b. The metal interconnections 225a and 225b may be formed at a similar or the same level. The two via pads 240a and 240b may be formed at a similar or the same level as well. The redistribution structures 265a and 265b and the IO pins 270a and 270b may be formed at a similar or the same level as well.

The top surfaces of the metal interconnections 225a and 225b may be formed on a different level from top surfaces of the via pads 240a and 240b. The top surfaces of the TSVP 230a and 230b may be formed at a similar level or the same level as the via pads 240a and 240b, and may be formed at a similar level or the same level as the top surface of the via pads 240a and 240b.

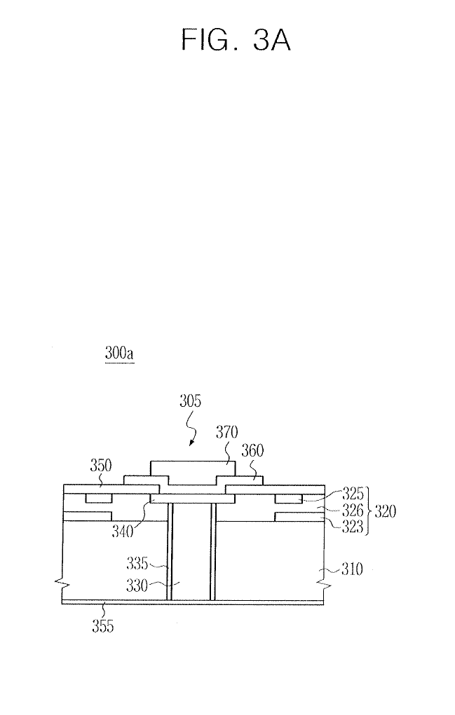

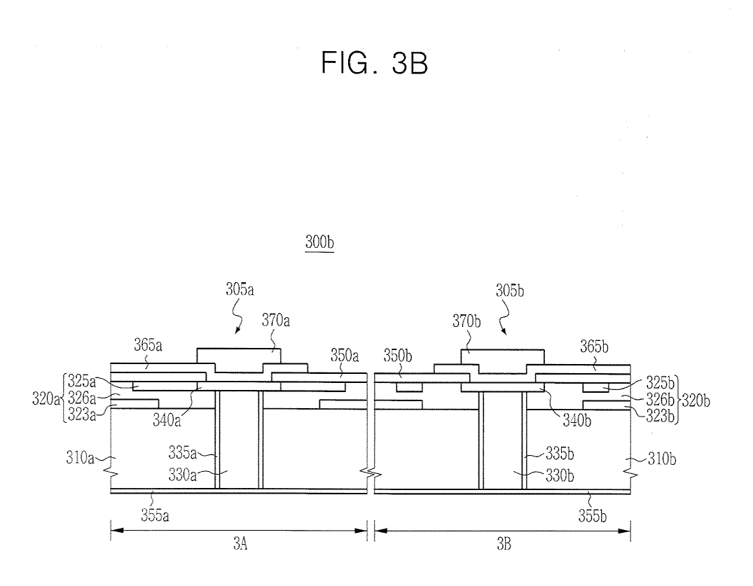

FIG. 3A is a cross-sectional view illustrating a semiconductor device according to still another example embodiment of the present general inventive concept. Referring to FIG. 3A, a semiconductor device 300a according to example embodiments of the present general inventive concept includes a circuitry layer 310, a metal interconnection layer 320, an IO part 305 including a TSVP 330. The schematic descriptions of the circuitry layer 310, the metal interconnection layer 320, the TSVP 330 and the IO part 305 will be omitted, and the elements will be schematically understood with reference to FIGS. 1A to 2B and the descriptions thereof.

The metal interconnection layer 320 can include a multilayer structure of metal interconnections 323 and 325 and a protection layer 326. As illustrated in FIG. 3A, the metal interconnections 323 and 325 may include upper metal interconnections 325 and lower metal interconnections 323. While the metal interconnection layer 320 may include more metal interconnections, only two metal interconnections 323 and 325 are illustrated for the sake of clarity. As illustrated in FIG. 3A, the upper metal interconnections 325 may be formed on an uppermost part of the metal interconnection layer 320. The description of the protection layer 326 may be schematically understood with reference to FIGS. 1A to 2B, and the descriptions thereof. The IO part 305 may include a TSVP 330, a barrier metal film 335, a via pad 340, a contact pad 360 and an IO pin 370. The elements may be schematically understood with reference to FIGS. 1A to 2B, and the descriptions thereof.

In the example embodiments of the present general inventive concept, the TSVP 330 may be formed of copper and surrounded by the barrier metal film 335. The description of the barrier metal film 335 may be schematically understood with reference to FIGS. 1A to 2B, and the descriptions thereof. The TSVP 330 may be electrically insulated from the metal interconnections 323 and 325 formed in the metal interconnection layer 320. In particular, it may be electrically insulated from the uppermost metal interconnections 325 of the metal interconnections 323 and 325 formed in the metal interconnection layer 320.

The via pad 340 may be formed in the metal interconnection layer 320. The via pad 340 may be formed at the same level as the upper metal interconnections 325. The via pad 340 may be electrically insulated from the metal interconnections 323 and 325.

An upper passivation layer 350 may be formed on the metal interconnection layer 320. The upper passivation layer 350 may be formed of at least one of silicon oxide, silicon nitride, silicon oxynitride and one or more polyimides.

A contact pad 360 may be formed on the upper passivation layer 350. The description of the contact pad 360 may be schematically understood with reference to FIGS. 1A and 2A, and the descriptions thereof. In the present example embodiment, a barrier metal layer (not illustrated) may be formed between the contact pad 360 and the via pad 340. In example embodiments of the present general inventive concept, it is illustrated that the contact pad 360 may be directly formed on the via pad 340 as well.

A lower passivation layer 355 may be formed on a surface below the circuitry layer 310. As illustrated in FIG. 3A, although the lower passivation layer 355 may cover the entire surface below the circuitry layer 310 and the entire bottom surface of the TSVP 330, the bottom surface of the TSVP 330 may be exposed in one or more portions. The lower passivation layer 355 may be formed of at least one of silicon oxide, silicon nitride, silicon oxynitride and various polyimides.

FIG. 3B is a cross-sectional view illustrating a semiconductor device according to example embodiments of the present general inventive concept. Referring to FIG. 3B, a semiconductor device 300b according to example embodiments includes a first region 3A and a second region 3B. The regions include a first and a second circuitry layers 310a and 310b, a first and a second metal interconnection layers 320a and 320b, a first and a second IO parts 305a and 305b including a first and a second TSVPs 330a and 330b, respectively. The schematic descriptions of the circuitry layers 310a and 310b, the metal interconnection layers 320a and 320b, the TSVPs 330a and 330b and the IO parts 305a and 305b will be omitted, and the elements will be schematically understood with reference to FIGS. 1A, 2A, and 3A, and the descriptions thereof. Metal interconnections 325a and 325 may be similar to or the same as metal interconnection 325 illustrated in FIG. 3A and described above, or as described in detail below. Metal interconnections 323a and 323b may be similar to or the same as metal interconnection 323 illustrated in FIG. 3A and described above. Protection layers 326a and 326b may be similar to or the same as metal interconnection 326 illustrated in FIG. 3A and described above, or similar to or the same as metal interconnections 226a and 226b illustrated in FIG. 2B and described above. Lower passivation layers 355a and 355b may be similar to or the same as lower passivation layer 325 illustrated in FIG. 3A and described above, and barrier metal films 335a and 335b may be the same as or similar to the barrier metal film 335 illustrated in FIG. 3A and described above. Upper passivation layers 350a and 350b may be similar to or the same as upper passivation layer 350 illustrated in FIG. 3A and described above.

The via pad 340a of the region 3A may be electrically connected to the metal interconnections 325a of the metal interconnection layer 320a, and the via pad 340b of the region 3B may be electrically insulated from the metal interconnections 325b of the metal interconnection layer 320b. That is, the metal interconnections 325a of the region 3A may be formed to be electrically of physically connected to the via pad 340a, and the metal interconnections 325b of the region 3B may be formed not to be electrically or physically connected to the via pad 340b. The IO part 305a of the region 3A may operate the semiconductor device 300b or transmit a data or voltage signal required during an operation. The IO part 305b of the region 3B may transmit a chip select signal selecting the semiconductor device 300b.

The upper metal interconnections 325a and 325b may be formed at the same level. The via pads 340a and 340b may also be formed at the same level. The upper metal interconnections 325a and 325b and the via pads 340a and 340b may be formed at the same level. The redistribution structures 365a and 365b and the IO pins 370a and 370b may be formed at the same level as well.

In example embodiments of the present general inventive concept, the redistribution structures 365a and 365b may include interconnection structures and via structures.

Elements that are not described or are briefly described may be understood with reference to FIGS. 1A to 3A and the descriptions thereof.

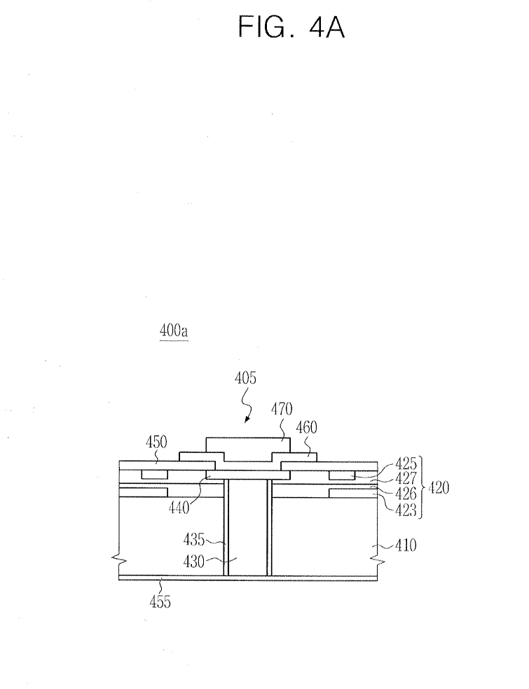

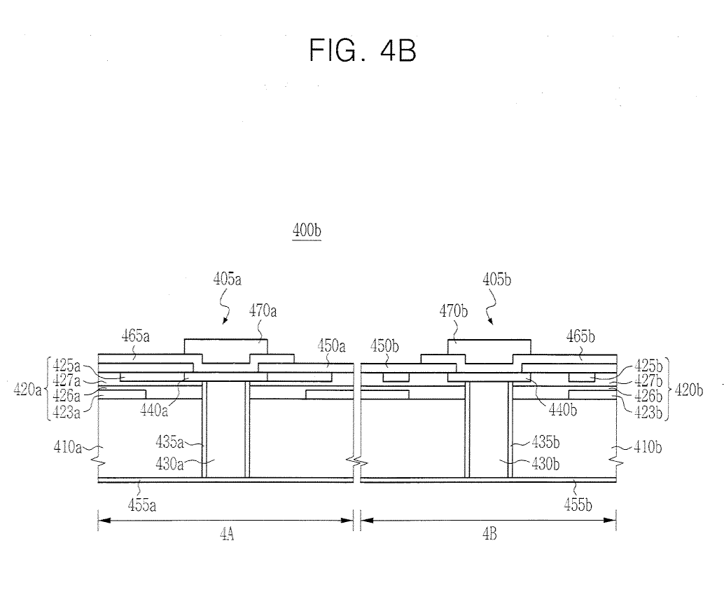

FIG. 4A illustrates a cross-sectional view of a semiconductor device according to exemplary embodiments of the present general inventive concept. Referring to FIG. 4A, a semiconductor device 400a can include a circuitry layer 410, a metal interconnection layer 420, an IO part 405 including a TSVP 430. The schematic descriptions of the circuitry layer 410, the metal interconnection layer 420, the TSVP 430 and the IO part 405 will be omitted, and the elements will be schematically understood with reference to FIGS. 1A to 3B and the descriptions thereof.

In the semiconductor device 400a according to example embodiments of the present general inventive concept, a bottom surface of a via pad 440 may be formed at a lower level than top surfaces of uppermost metal interconnections 425. The bottom surface of the via pad 440 may be formed at a higher level than bottom surfaces of the uppermost metal interconnections 425. A top surface of the via pad 440 may be formed at a higher level than the bottom surfaces of the uppermost metal interconnections 425. The top surface of the via pad 440 may be formed at a higher level than the top surfaces of the uppermost metal interconnections 425.

The TSVP 430 and/or the via pad 440 may be formed so as not to be electrically or physically connected to the metal interconnections 423 and 425.

In example embodiments of the present general inventive concept, protection layers 426 and 427 may be formed in a multilayer structure, and may include a lower protection layer 426 and an upper protection layer 427. A top surface of the lower protection layer 426 may be formed at a lower level than that of the TSVP 430.

FIG. 4B illustrates a cross-sectional view of a semiconductor device according to yet another example embodiment of the present general inventive concept. Referring to FIG. 4B, a semiconductor device 400b includes two regions, i.e., a first region 4A and a second region 4B. The regions include a first and a second circuitry layers 410a and 410b, a first and a second metal interconnection layers 420a and 420b, a first and a second IO parts 405a and 405b including a first and a second TSVPs 430a and 430b, respectively. The schematic descriptions of the circuitry layers 410a and 410b, the metal interconnection layers 420a and 420b (including the metal interconnections 423a and 423b, metal interconnections 425a and 425b, and protection layers 426a and 426b included in the metal interconnection layers 420a and 420b, respective), the barrier metal films 435a and 435b, the lower passivation layers 450a and 450b, the TSVPs 430a and 430b and the IO parts 405a and 405b will be omitted, and the elements will be schematically understood with reference to FIGS. 1A to 4A and the descriptions thereof. The semiconductor device 400b according to the present example embodiment may be understood with particular reference to the semiconductor device 400a illustrated in FIG. 4A.

In example embodiments of the present general inventive concept, the IO parts 405a and 405b include the TSVPs 430a, 430b, via pads 440a and 440b, redistribution structures 465a and 465b, and IO pins 470a and 470b. Each of the redistribution structures 465a and 465b may function as a contact pad, and may be formed in an interconnection structure to electrically connect the IO parts 405a and 405b to other IO parts disposed on other locations. When the redistribution structures 465a and 465b function as contact pads will be understood with reference to FIGS. 1A, 2A, 3A and 4A and the descriptions thereof.

The TSVP 430a and 430b may be formed at a higher level than bottom surfaces of the via pads 440a and 440b. The bottom surfaces of the via pads 440a and 440b may be formed at a lower level than top surfaces of the metal interconnections. The TSVP 430b of the region 4B may be formed so as not to be electrically or physically connected to the metal interconnections 423b and 425b.

The metal interconnections 423a and 425a of the region 4A may be electrically or physically connected to the via pad 440a, and the metal interconnections 423b and 425b of the region 4B may be formed so as not to be electrically or physically connected to the via pad 440b. That is, the metal interconnections 423b and 425b of the region 4B may be spaced apart from the via pad 440b. Therefore, the TSVP 430a of the region 4A may be electrically connected to the metal interconnections 425a of the metal interconnection layer 420a and the TSVP 430b of the region 4B may be electrically insulated from the metal interconnections 425b of the metal interconnection layer 420b. The IO part 405a of the region 4A may operate the semiconductor device 400b or transmit a data or voltage signal required during an operation. The IO part 405b of the region 4B may transmit a chip select signal selecting the semiconductor device 400b. The metal interconnections 425a and 425b may be formed at the same level. The two via pads 440a and 440b may be formed at the same level as well. The redistribution structures 465a and 465b and the IO pins 470a and 470b may be formed at the same level as well.

Top surfaces of the metal interconnections 425a and 425b may be formed on a different level from those of the via pads 440a and 440b. The top surfaces of the TSVPs 430a and 430b may be formed at a similar level or the same level as the via pads 440a and 440b, and may be formed at a similar level or the same level as those of the via pads 440a and 440b.

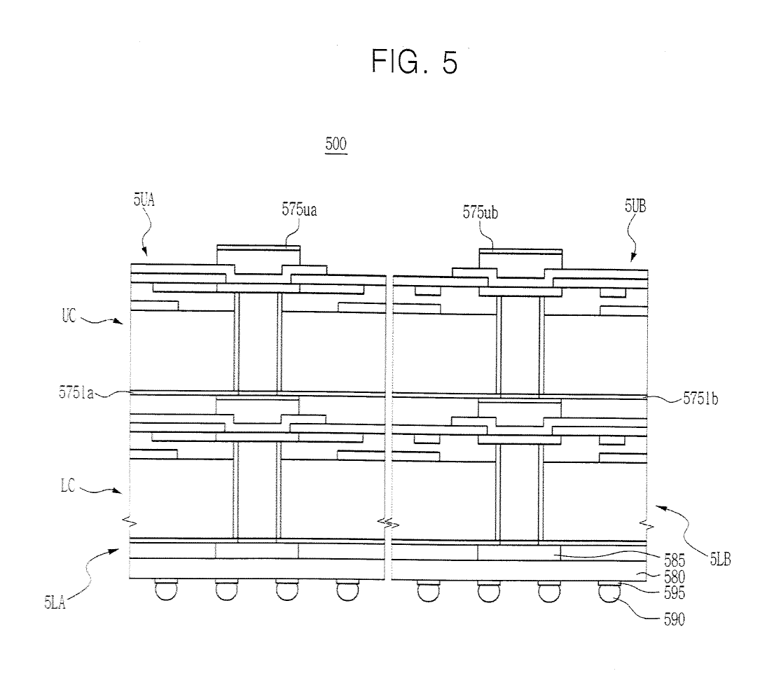

FIG. 5 illustrates a cross-sectional view of a stacked structure of a semiconductor device according to an example embodiment of the present general inventive concept. Referring to FIG. 5, a stacked structure 500 of a semiconductor device according to example embodiments of the present general inventive concept can include an upper chip (UC), and a lower chip (LC). The upper chip UC can include a first region 5UA and a second region 5UB, the lower chip LC includes a third region 5LA and a fourth region SLB. Each region can include a circuitry layer, a metal interconnection layer, and an IO part including a TSVP. For the sake of simplicity, reference marks of the elements are not indicated. The elements of the present example embodiment will be schematically understood with reference to FIGS. 1A to 4B and the descriptions thereof.

Via pads can be formed in the first region 5UA, the second region 5UB of the upper chip UC, and the third region 5LA of the lower chip LC may be electrically or physically connected to metal interconnections of the metal interconnection layer, and via pads formed in the fourth region 5LB of the lower chip LC may be electrically or physically insulated from metal interconnections of the metal interconnection layer. Via plugs formed in the first region 5UA, the second region 5UB of the upper chip UC, and in the third region 5LA of the lower chip LC may be electrically or physically connected to the metal interconnection of the metal interconnection layer, and the via pads formed in the fourth region 5LB of the lower chip LC may be electrically or physically insulated from the metal interconnections of the metal interconnection layer. The metal interconnection may be an uppermost metal interconnection among the metal interconnections formed in the metal interconnection layer.

Upper barrier metal films 575ua and 575ub may be formed on IO pins. The upper barrier metal films 575ua and 575ub may be formed of at least one of Ti/TiN, TaN, nickel, aluminum, and an alloy thereof.

Lower barrier metal films 5751a and 5751b may be formed at lower portions of the via plugs. The lower barrier metal films 5751a and 5751b may be formed of at least one of Ti/TiN, TaN, nickel, aluminum, and an alloy thereof.

The IO parts of the first region 5UA of the upper chip UC and the third region 5LA of the lower chip LC may operate the stacked structure 500 of the semiconductor device or transmit a data or voltage signal required during an operation. The IO parts of the second region 5UB of the upper chip UC and the fourth region 5LB of the lower chip LC may transmit a chip select signal selecting the stacked structure 500 of the semiconductor device.

While it is illustrated in the drawing that various elements are exposed on top surfaces of the chips UC and LC, the chips may be covered with insulating materials.

The stacked structure 500 of the semiconductor device according to example embodiments may be disposed on a printed circuit board (PCB) 580. A plurality of solder balls 590 and a plurality of solder lands 595 may be formed on a bottom surface of the PCB 580. The via plugs of the lower chip LC of the stacked structure 500 of the semiconductor device may be electrically connected to the solder balls through metal connectors 585.

Methods of fabricating semiconductor devices according to example embodiments of the present general inventive concept will be described below.

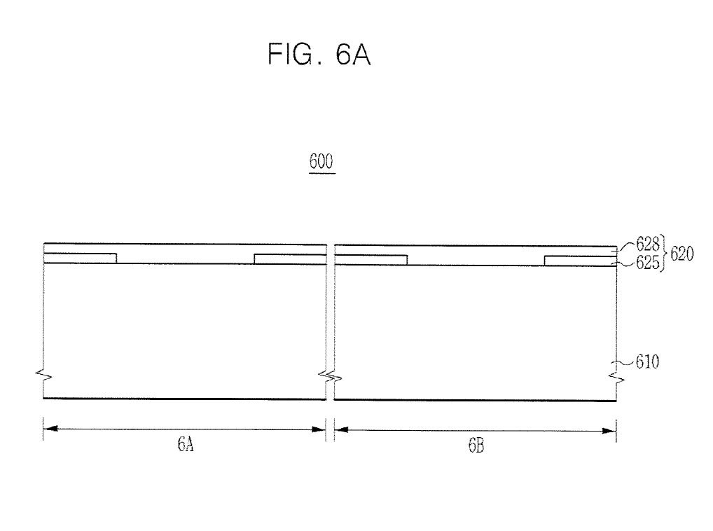

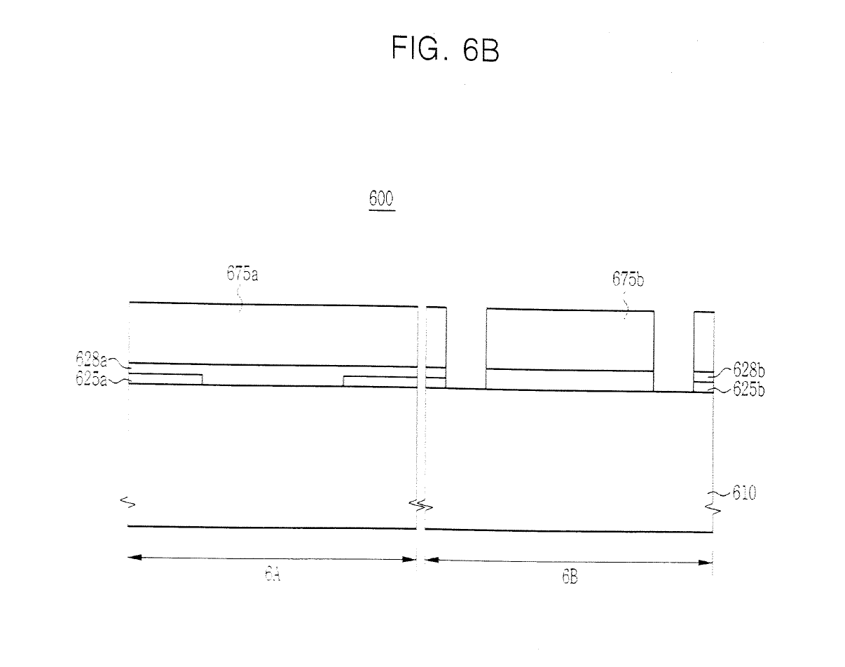

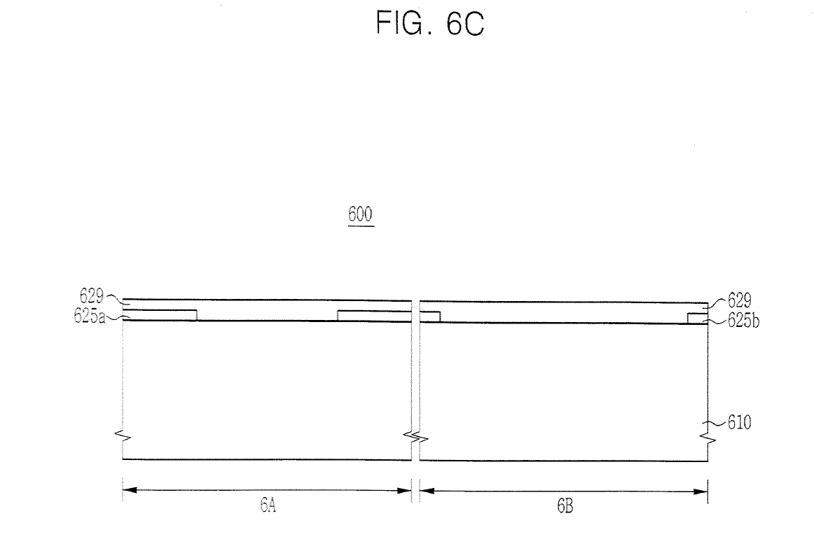

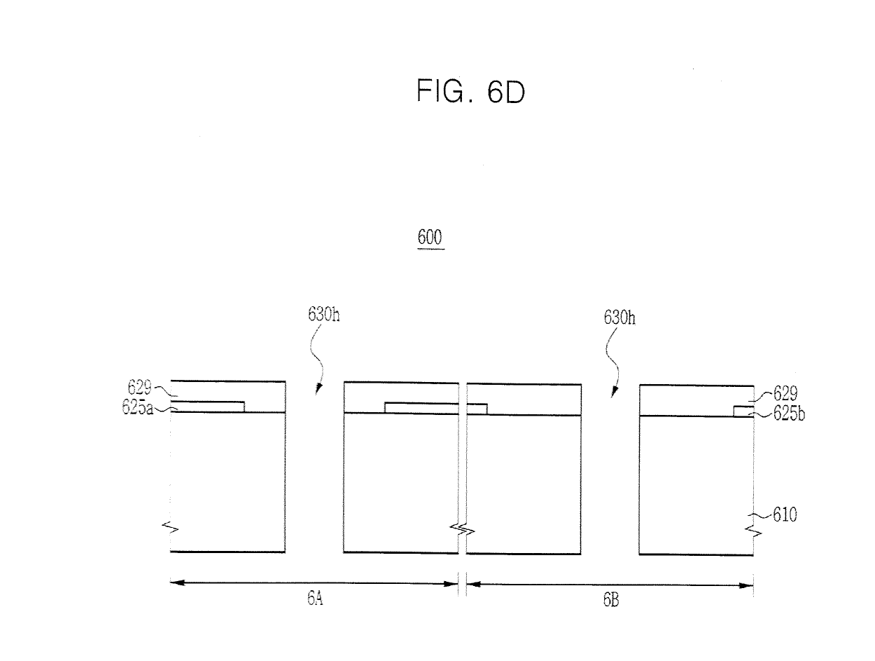

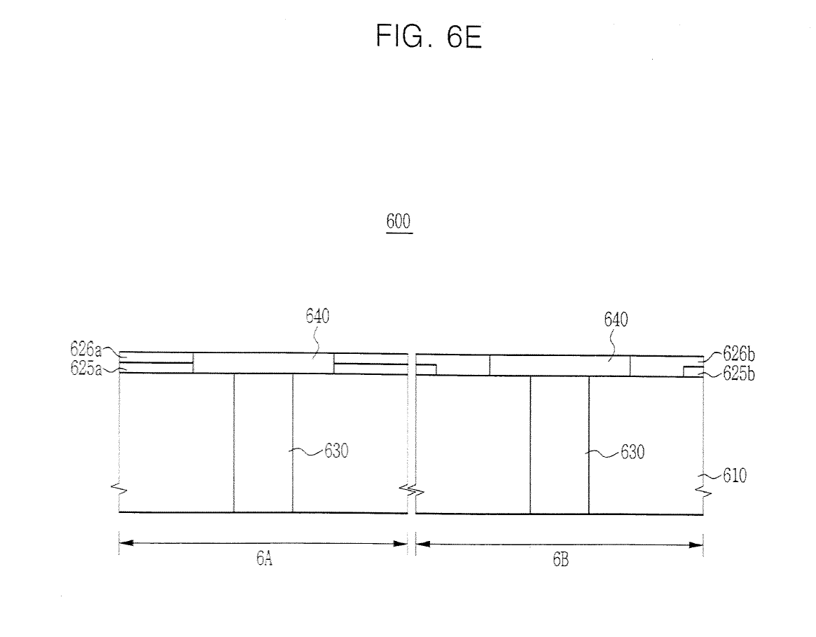

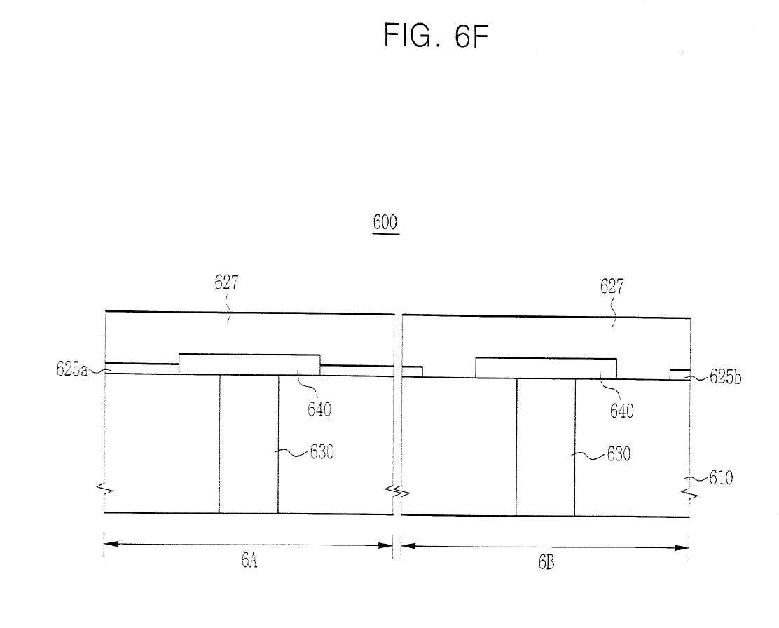

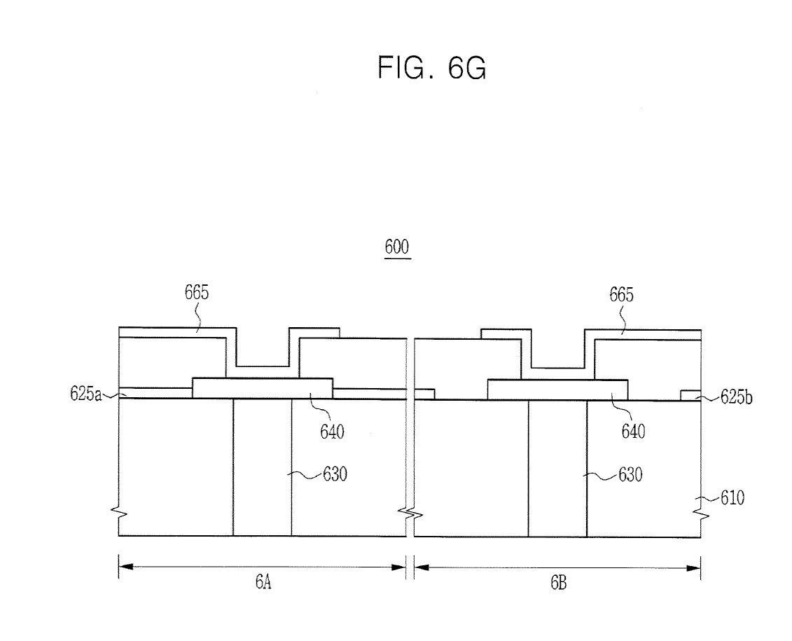

FIGS. 6A to 6G are cross-sectional views illustrating a method of fabricating a semiconductor device 600 including copper pads according to example embodiments of the present general inventive concept. Referring to FIG. 6A, a semiconductor chip including a region 6A and a region 6B, each of which includes a circuitry layer 610 and a metal interconnection layer 620, is prepared. The metal interconnection layer 620 may be protected by an insulating material. The metal interconnection layer 620 may include multilayer metal interconnections 625 having a copper interconnection. Although FIG. 6 illustrates a single-layer metal interconnections 625, metal interconnections may be formed on other levels, illustrations of which are omitted for the sake of clarity. The illustrated metal interconnections 625 may be metal interconnections 625 formed on an uppermost layer among multilayer metal interconnections formed in the metal interconnection layer 620. A first protection layer 628 (or, as illustrated in FIG. 6B, first protection layers 628a and 628b) may be formed in the metal interconnection 625. The first protection layer 628 may be formed of at least one of a silicon oxide layer, a silicon nitride layer, a silicon oxynitride layer and various polyimides.

Referring to FIG. 6B, etch mask patterns 675a and 675b are formed, and the metal interconnections 625 of the region 6B are patterned. The metal interconnections 625 formed in the region 6B are cut not to be in physical contact with a TSVP and a via pad that will be formed in the region 6B. Although FIG. 6B illustrates that end parts of the metal interconnections 625a and 625b formed in the region 6B can be cut, the middle parts may also be cut. The etch mask patterns 675a and 675b may be a photoresist, a hard mask or a combination thereof. The metal interconnections 625a and 625b may be cut by laser cutting.

Referring to FIG. 6C, a second protection layer 629 is formed on the metal interconnections 625a and 625b. The second protection layer 629 may be formed of at least one of silicon oxide, silicon nitride, silicon oxynitride and various polyimides. Although FIG. 6C illustrates that the first protection layer 628 and the second protection layer 629 have the same surface level, a surface of the second protection layer 629 may be formed at a higher level than that of the first protection layer 628.

Referring to FIG. 6D, through silicon via holes 630h to form TSVPs 630 can be formed. The through silicon via holes 630h may be formed by an anisotropic etching method, a laser drilling method, or any other suitable methods to form the exemplary embodiments of the present general inventive concept.

Referring to FIG. 6E, the through silicon via holes 630h can be filled with a conductive metal, e.g., copper, to form TSVPs 630 and via pads 640. When the TSVPs 630 are formed of copper, a plating method may be used. The plating method can include filling the through silicon via holes 630h with a conductive metal from a lower part toward an upper part to form the TSVPs 630. The via pads 640 may be formed of copper using the plating method. Although not illustrated in FIGS. 6A-6G, the via pads 640 may be formed using one or more methods in order to achieve the exemplary embodiments of the present general inventive concept. For example, when the TSVPs 630 are formed, after completing forming the TSVPs 630 on the top surface level of the circuitry layer 610, the via pads 640 may be formed. Also, the surfaces of the TSVPs 630 may be formed at a higher level than the top surface of the circuitry layer 610. The via pad 640 may be formed, and its top surface may be planarized using a CMP process to form the illustrated shape. Alternatively, the process of forming the TSVPs 630 and the via pads 640 may be continually and/or repeatedly performed. The shape of the formed semiconductor device 300 may be different from that illustrated in FIG. 6E depending on the forming the TSVP 630 and the via pad 640. However, it is a difference in shape, and such a difference is not to be regarded as a departure from the spirit and scope of example embodiments of the present general inventive concept. Barrier metal films (not illustrated) may be formed between the TSVPs 630 and the via pads 640. The barrier metal films may be formed of Ti/TiN, TaN, etc.

Referring to FIG. 6F, a third protection layer 627 may be formed on the metal interconnections 625a and 625b and the via pads 640. The third protection layer 627 may be formed of at least one of a silicon oxide layer, a silicon nitride layer, a silicon oxynitride layer and various polyimides.

Referring to FIG. 6G, openings exposing surfaces of via pads 640 can be formed, and redistribution structures 665 can be formed. The openings may be formed by an anisotropic etching method, and the redistribution structures 665 may be formed by extending from surfaces of the exposed via pads 640, sidewalls of the openings and an upper part of the third protection layer 627. For example, the redistribution structures 665 may horizontally extend forward and backward or left and right to be electrically or physically connected to via pads of another semiconductor chip that is not illustrated. In the example embodiments of the present general inventive concept, the redistribution structures 665 may be formed of a metal, e.g., copper, aluminum, tungsten, gold, silver or other metals. In example embodiments of the present general inventive concept, barrier metal films (not illustrated) may be formed between the via pads 640 and redistribution structures 665. The barrier metal films may be formed of Ti/TiN, TaN, etc. IO pins (not illustrated) filling the opening may be formed. For example, the semiconductor device illustrated in FIG. 1B according to example embodiments of the present general inventive concept may be completed. The IO pins may be formed of a metal.

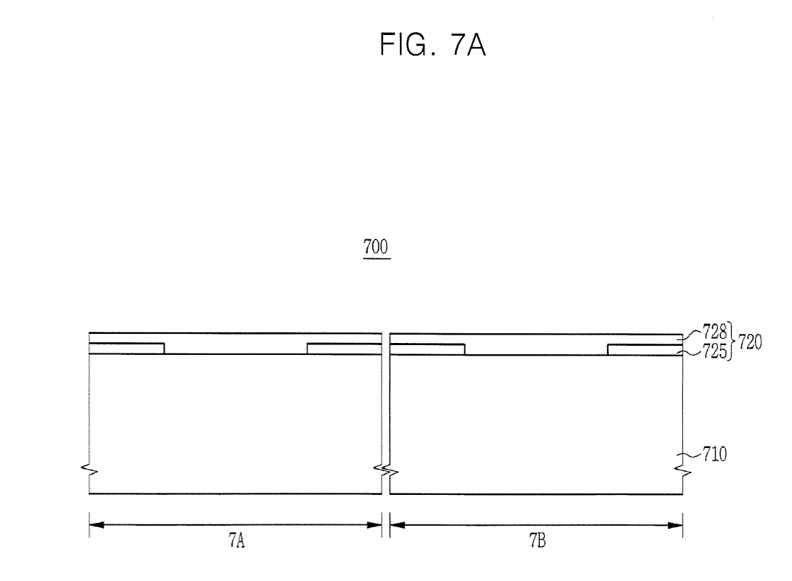

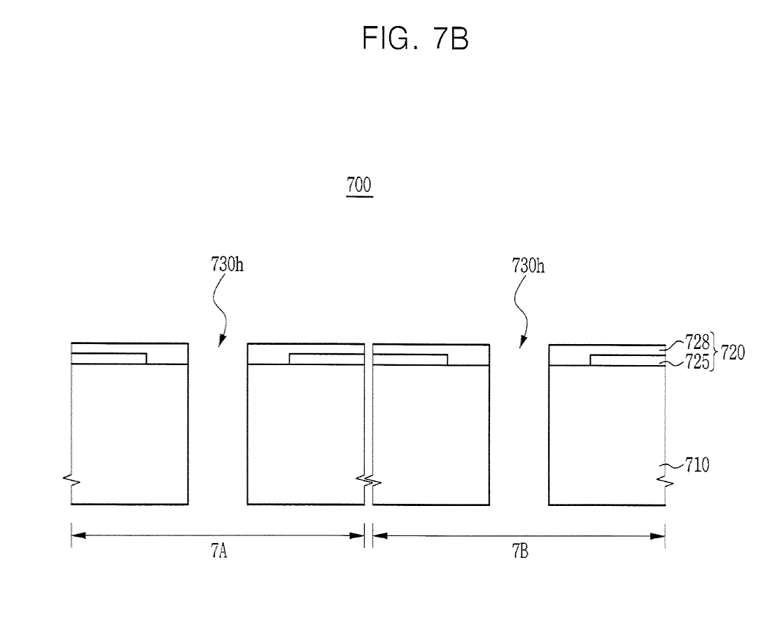

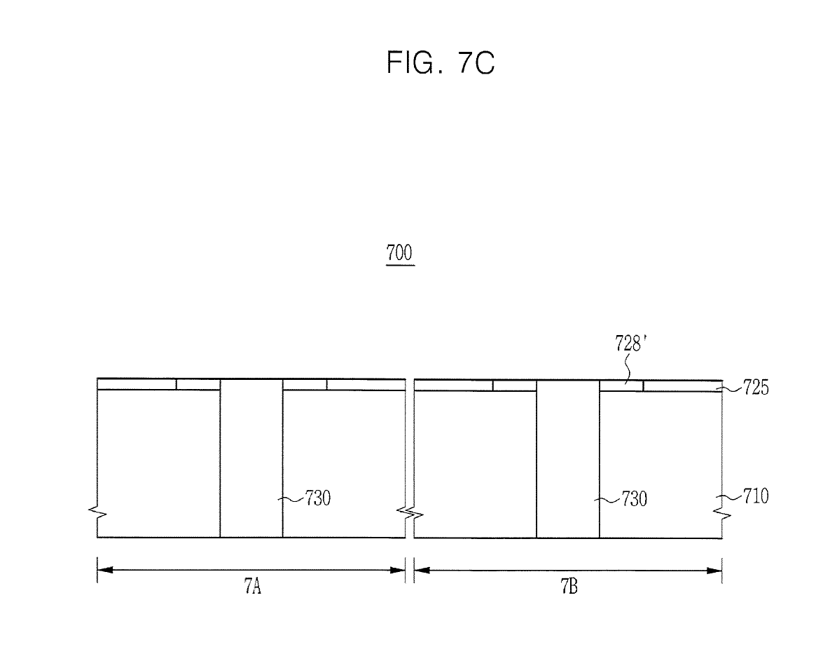

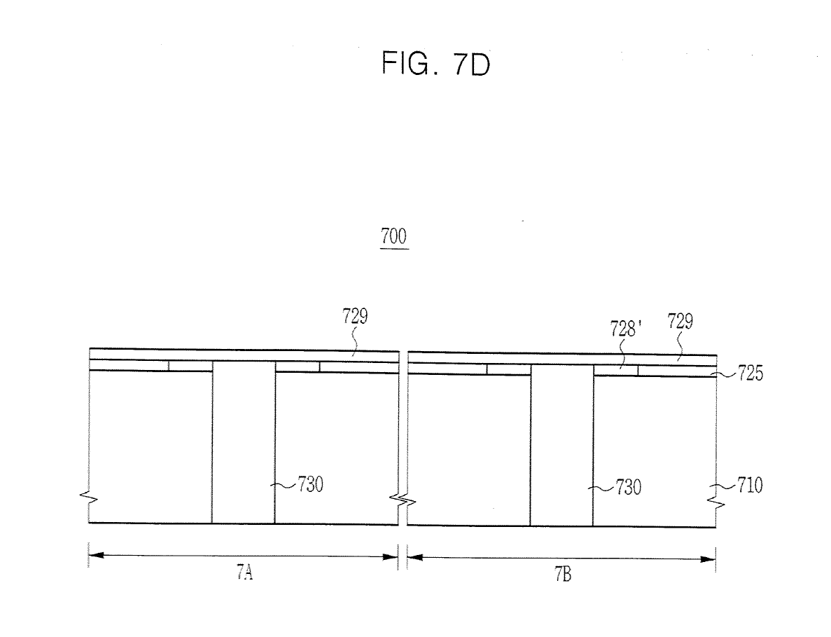

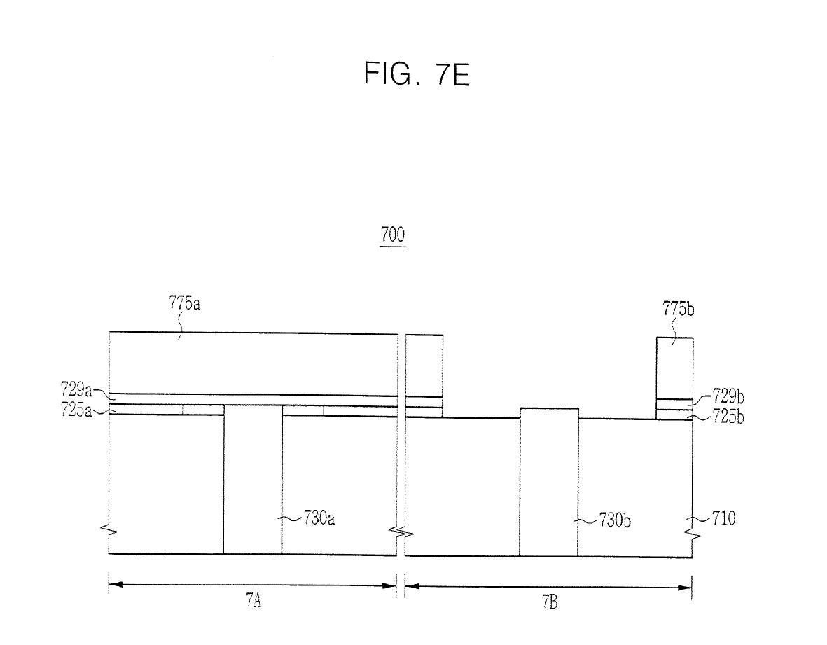

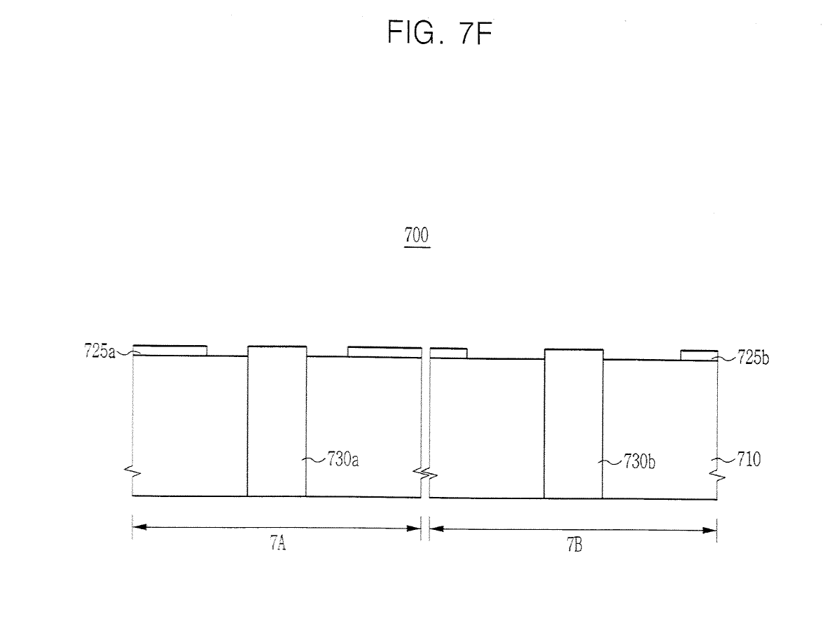

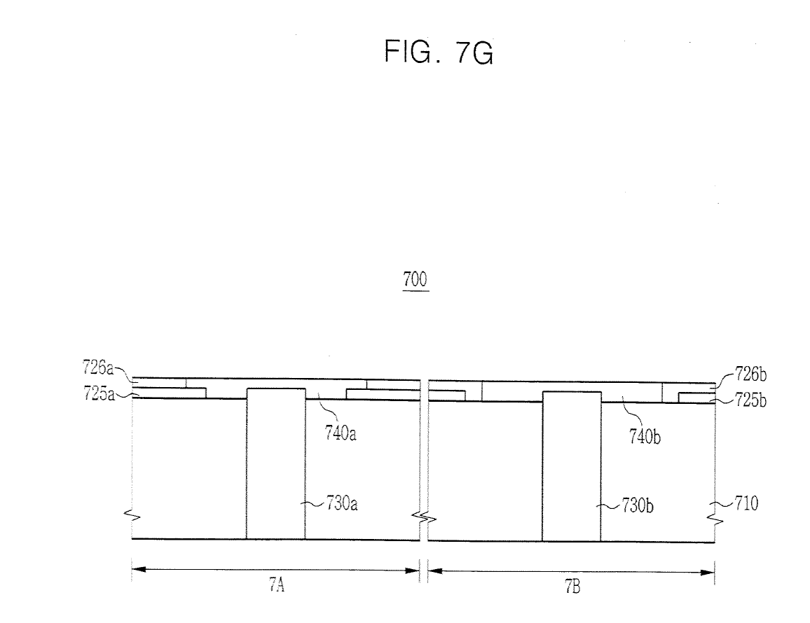

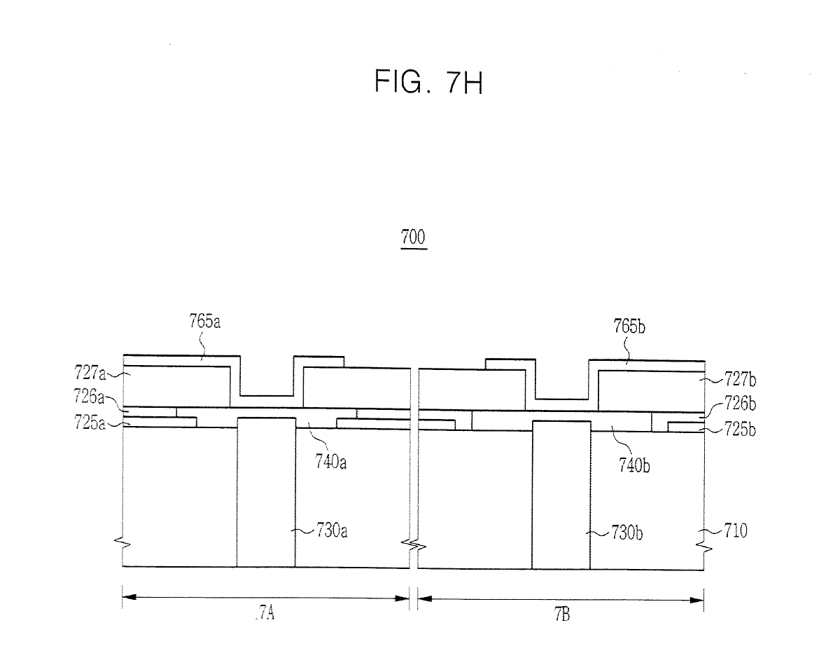

FIGS. 7A to 7H are cross-sectional views illustrating a method of fabricating a semiconductor device 700 according to example embodiments of the present general inventive concept. Referring to FIG. 7A, the semiconductor device 700 including a region 7A and a region 7B, each of which includes a circuitry layer 710 and a metal interconnection layer 720, can be formed. The detailed descriptions of the formation of the semiconductor device 700 will be understood with reference to FIG. 6A and the description thereof. The metal interconnection layer 720 includes metal interconnections 725 and a first sacrificial layer 728.

Referring to FIG. 7B, via holes 730h to form TSVPs may be formed. The through silicon via holes 730h may be formed by an anisotropic etching method, a laser drilling method or other suitable methods to achieve the exemplary embodiments of the present general inventive concept.

Referring to FIG. 7C, the through silicon via holes 730h are filled with a conductive metal, e.g., copper, to form TSVPs 730. A CMP process may be used to planarize top surfaces of the TSVPs 730. When the surfaces on which the CMP is performed are within a predetermined distance to surfaces of the metal interconnections 725, top surfaces of the TSVPs 730 may be formed at a predetermined level to the surfaces of the metal interconnections 725. The surfaces of the metal interconnections 725 to be exposed. That is, a first sacrificial layer 728′ may remain on the metal interconnections 725.

Referring to FIG. 7D, a second sacrificial layer 729 can be formed on the TSVPs 730, the metal interconnections 725 and the first sacrificial layer 728′. The second sacrificial layer 729 may be utilized as an etch mask or an etch buffer layer. The second sacrificial layer 729 may be formed of silicon oxide, silicon nitride or silicon oxynitride. When the first sacrificial layer 728′ and the second sacrificial layer 729 are formed of the same material, e.g., silicon oxide layers or silicon nitride layers, the first sacrificial layer 728′ and the second sacrificial layer 729 may have different etch rates depending on the formation method thereof, and thus it may be unnecessary to form the first sacrificial layer 728′ and the second sacrificial layer 729 using different materials.

Referring to FIG. 7E, etch masks 775a and 775b are formed and metal interconnections 725a and 725b of the region 7B can be cut. To avoid being physically connected to a via pad to be formed in the following process, end or middle parts of the metal interconnections 725b of the region 7B are removed. The parts of the metal interconnections 725b of the region 7B are removed by laser cutting. In the present process, an etch mask having the shape illustrated in FIG. 6B may be formed. The compatible two processes are illustrated. In the present process, top surfaces of the TSVP 730b of the region 7B may be exposed. In particular, the top surfaces of the TSVP 730b of the region 7B may be disposed at a higher level than a top surface of the circuitry layer 710. That is, the TSVP 730b of the region 7B may expose a side surface of an uppermost part. It is unnecessary to expose the top surface of the circuitry layer 710b. The sacrificial layers 728′ and 729 (of FIG. 7D) may be etched as much as only the metal interconnections 725b of the region 7B are cut, such that second sacrificial layers 729a and 729b remain. Only single-layer metal interconnections 725b are illustrated in FIG. 7E for the sake of clarity, and if multilayer metal interconnections were illustrated, the metal interconnection layer 720 would be exposed by a predetermined amount.

Referring to FIG. 7F, the etch masks 775a and 775b and the second sacrificial layers 729a and 729b can be removed. The surface of the circuitry layer may not be exposed, and the metal interconnections 725a and 725b can be exposed by a predetermined amount.

Referring to FIG. 7G, lower protection layers 726a and 726b and via pads 740a and 740b can be formed. The lower protection layers 726a and 726b can be formed, the via pads 740a and 740b can be formed, and then a CMP process may be performed for planarization. The via pads 740a and 740b may be formed by patterning the lower protection layers 726a and 726b to form via pad openings, and then filling the via pad openings. Alternatively, after metal layers for via pads are formed, the via pads 740a and 740b are formed by an etching method, and then the lower protection layers 726a and 726b may be formed. The two processes may be appropriately selected depending on the kind of a metal for forming the via pads 740a and 740b or the kind of a process of forming the via pad, e.g., a deposition method or a plating method.

Referring to FIG. 7H, upper protection layers 727a and 727b can be formed, openings exposing top surfaces of the via pads 740a and 740b can be formed, and redistribution structures 765a and 765b can be formed. The redistribution structures 765a and 765b may be formed by extending from the top surfaces of the via pads 740a and 740b, sidewalls of the openings and top surfaces of the upper protection layers 727a and 727b. IO pins (not illustrated) filling the openings may also be formed. For example, the semiconductor device illustrated in FIG. 2B according to example embodiments of the present general inventive concept may be completed.

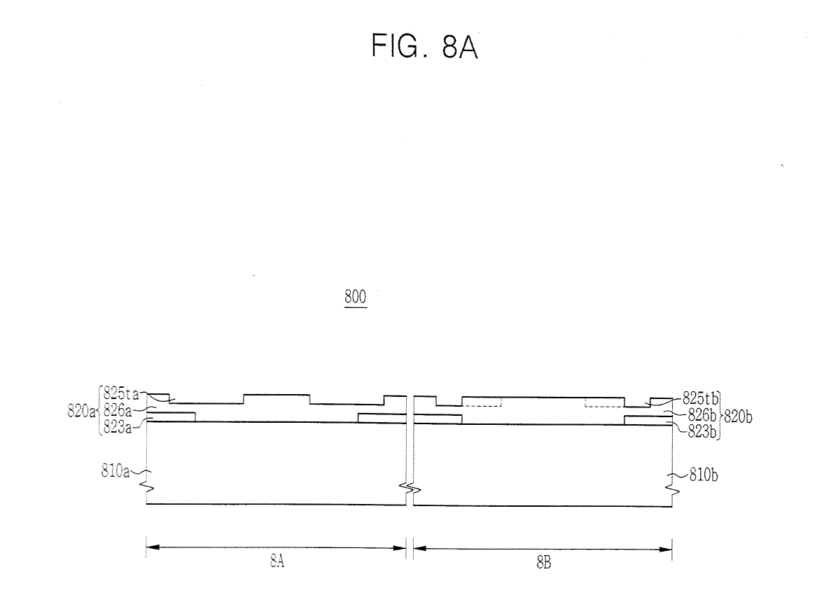

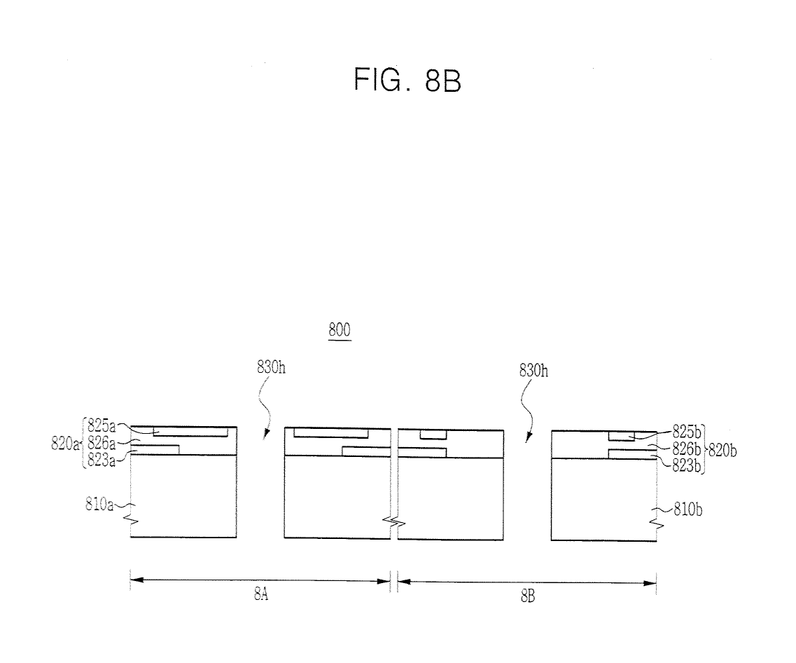

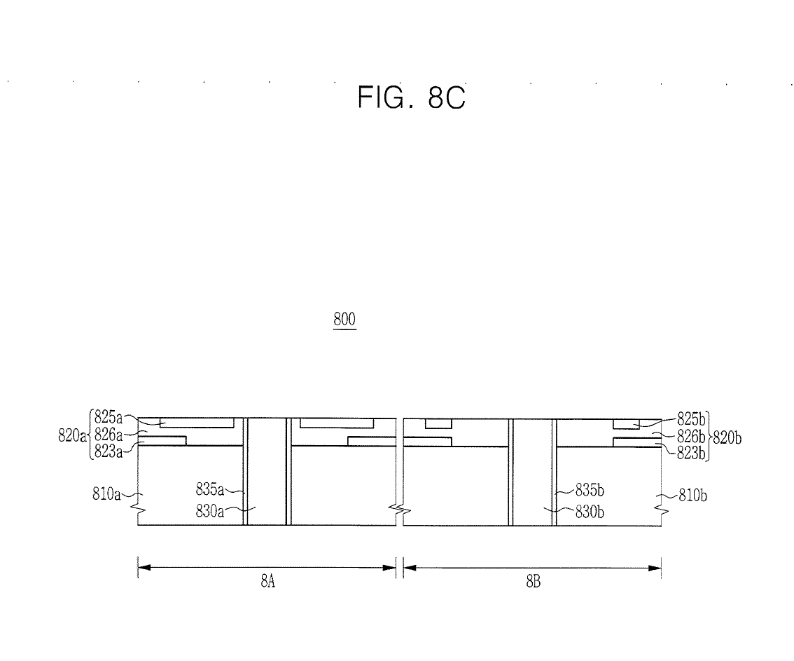

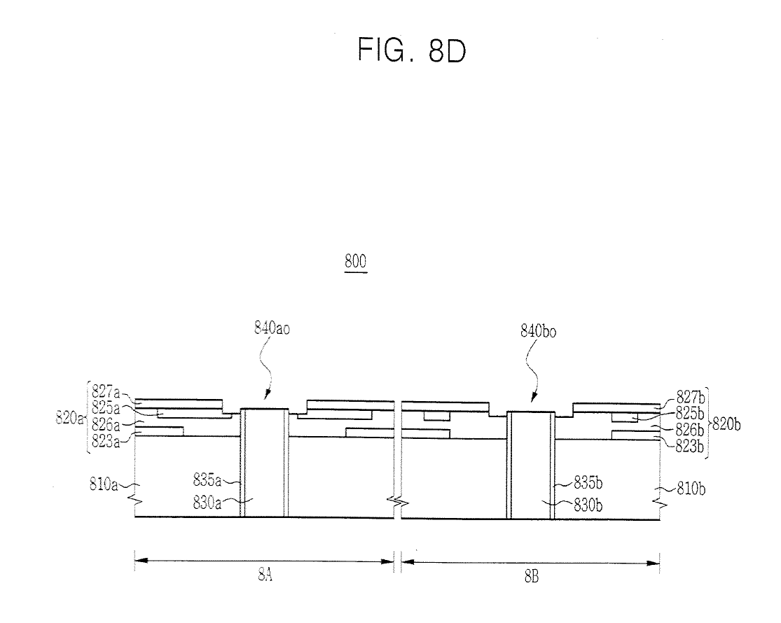

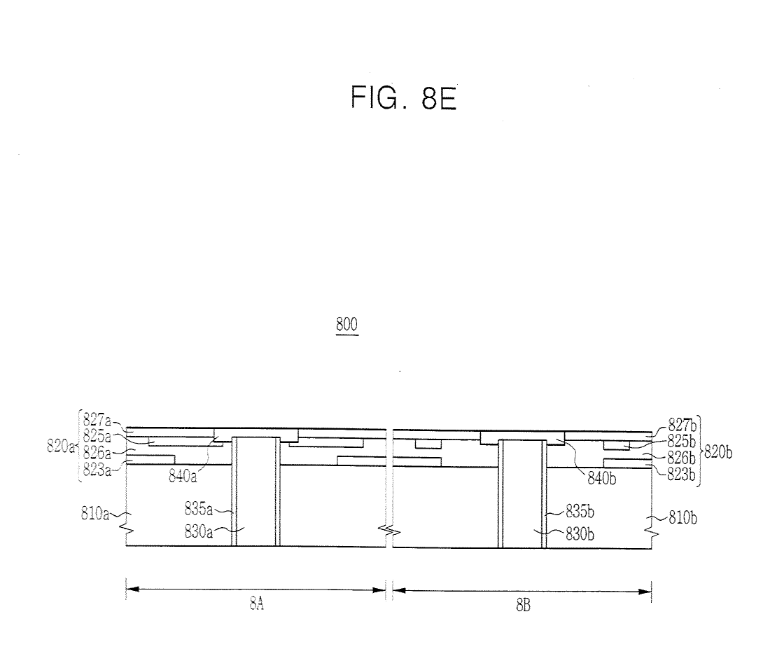

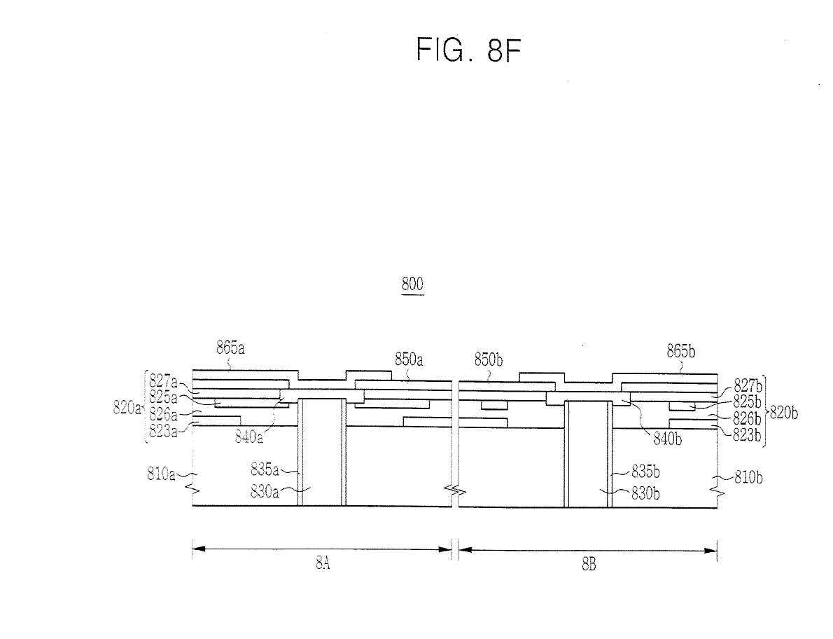

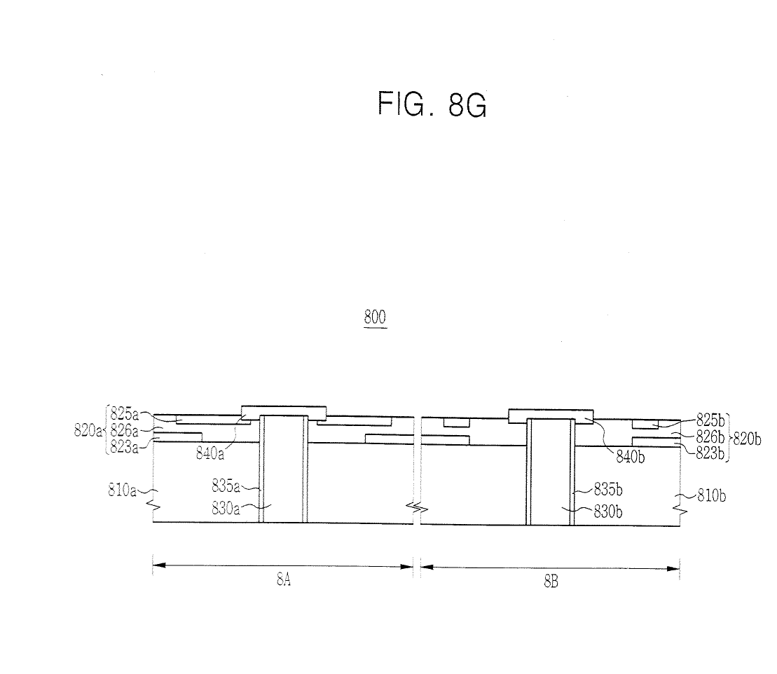

FIGS. 8A to 8G are schematic cross-sectional views illustrating a method of fabricating a semiconductor device 800 according to example embodiments of the present general inventive concept. Referring to FIG. 8A, a semiconductor device 800 including a first region 8A and a second region 8B is formed. The regions 8A and 8B may include a first and a second circuitry layers 810a and 810b, and a first and a second metal interconnection layers 823a and 823b. The metal interconnection layers 820a and 820b may include trenches 825ta and 825tb to form uppermost metal interconnections. The metal interconnection layers 820a and 820b may include multilayer metal interconnections 823a and 823b and lower protection layers 826a and 826b. FIG. 8A illustrates two-layer metal interconnections. The trenches 825ta and 825tb to form uppermost metal interconnections can be formed on the lower protection layers 826a and 826b. The size or width of the first trenches 825ta of the region 8A may be greater or wider than that of the second trenches 825tb. Compared to the first trenches 825ta, portions indicated in a dotted line in the second trenches 825tb can be portions that are not formed as trenches. The portions indicated in a dotted line are provided to be insulated from the via pads in the following process, the detailed description of which is provided below. The lower protection layers 826a and 826b may be formed of at least one of silicon oxide, silicon nitride, and silicon oxynitride.

Referring to FIG. 8B, uppermost metal interconnections 825a and 825b filling the trenches 825ta and 825tb can be formed, and through silicon via holes 830h to form TSVPs are formed in the regions. The uppermost metal interconnections 825a and 825b may be formed of copper. When the uppermost metal interconnections 825a and 825b are formed of copper, ultimately, a CMP process may be performed. The through silicon via holes 830h to form TSVPs can be formed.

Referring to FIG. 8C, barrier metal films 835a and 835b can be formed on sidewalls of the through silicon via holes 830h, and TSVPs 830a and 830b filled with a conductor such as copper are formed in the through silicon via holes 830h. A CMP process may also be performed.

Referring to FIG. 8D, upper protection layers 827a and 827b can be formed, and openings 840ao and 840bo to form the via pads are formed. A part of the uppermost metal interconnections 825a may be exposed in the first opening 840ao of the region 8A. The uppermost metal interconnections 825b may not exposed in the second opening 840bo of the region 8B. The upper protection layers 827a and 827b may be formed of one or more materials used for the lower protection layers 826a and 826b. The upper protection layers 827a and 827b may be formed of the same material as or a different material from that used for the lower protection layers 826a and 826b.

Referring to FIG. 8E, the openings 840ao and 840bo can be filled with copper to perform a CMP process, so that via pads 840a and 840b can be formed. The via pad 840a of the region 8A may be electrically or physically connected to the uppermost metal interconnections 825a. The via pad 840b of the region 8B may be electrically or physically detached from the uppermost metal interconnections 825b.

Referring to FIG. 8F, passivation layers 850a and 850b can be formed, openings exposing top surfaces of the via pads 840a and 840b can be formed, and redistribution structures 865a and 865b can be formed. The passivation layers 850a and 850b may be formed on at least a portion of or the entire surface of the substrate, and may be formed of at least one of silicon oxide, silicon nitride, silicon oxynitride and various polyimides. The openings may be formed through photolithography. The redistribution structures 865a and 865b may be formed so as to extend from top surfaces of the exposed via pads 840a and 840b, sidewalls of the openings, and top surfaces of the passivation layers 850a and 850b. The redistribution structures 865a and 865b may longitudinally extend in a horizontal direction to be electrically or physically connected to other via pads. IO pins (not illustrated) can be formed on the redistribution structures 865a and 865b to fill the openings to complete a semiconductor device 800 according to example embodiments of the present general inventive concept.

FIG. 8G illustrates that the semiconductor device 800 may be formed by another process according to example embodiments of the present general inventive concept. When the surfaces of the uppermost metal interconnections 825a and 825b of the region 8A are exposed (e.g., as illustrated in FIG. 8C), via patterns 840a and 840b are formed. The via patterns 840a and 840b may be formed of copper using a plating method. During the process, barrier metal films (not illustrated) may be formed at a boundary between metals or between the TSVPs 830a and 830b and the via pads 840a and 840b. As illustrated in FIG. 8G, the via pad 840a of the region 8A may be electrically or physically connected to the uppermost metal interconnections 825a, and the via pad 840b of the region 8B may be electrically or physically insulated from the uppermost metal interconnections 825b. The semiconductor device 800 may be processed as illustrated in FIG. 8E or 8F. That is, the upper protection layer 827 may be formed, and the passivation layer 850 may be formed. When the upper protection layer 827 is formed, a CMP process may be omitted.

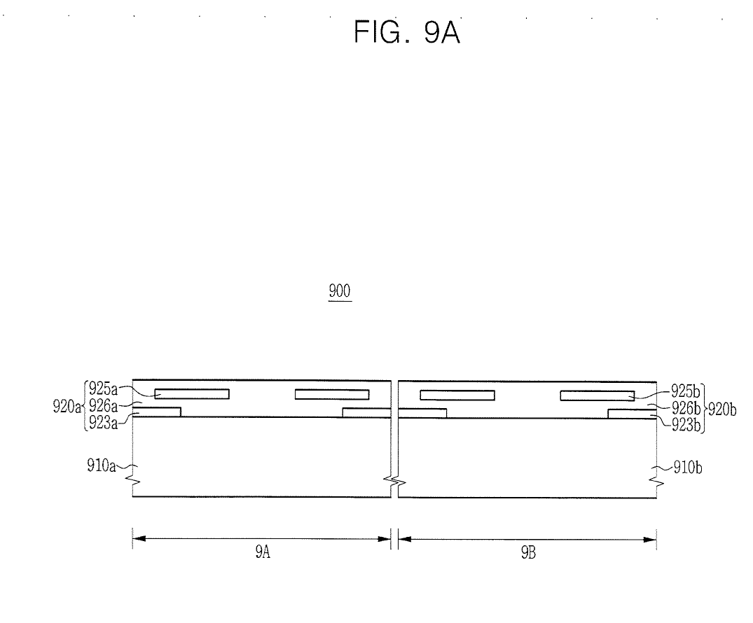

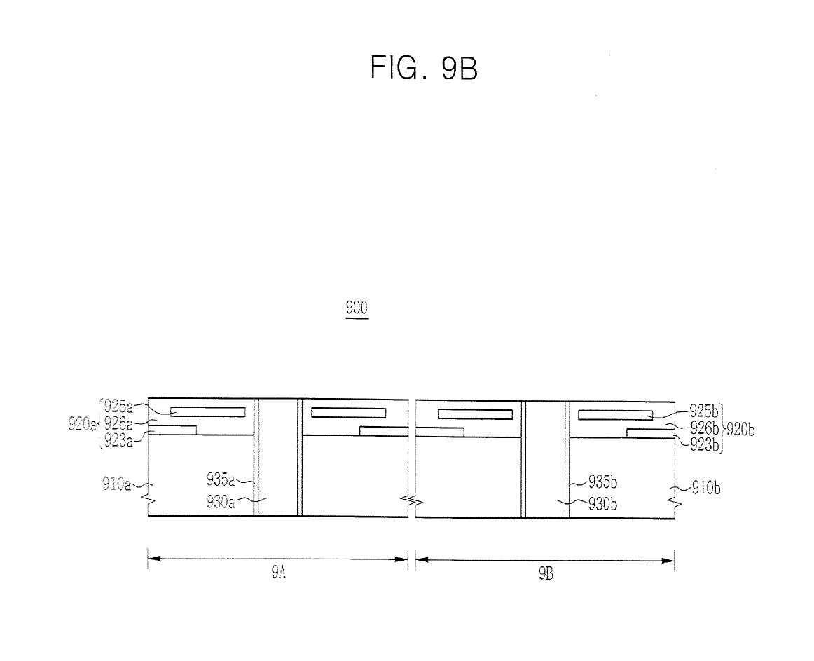

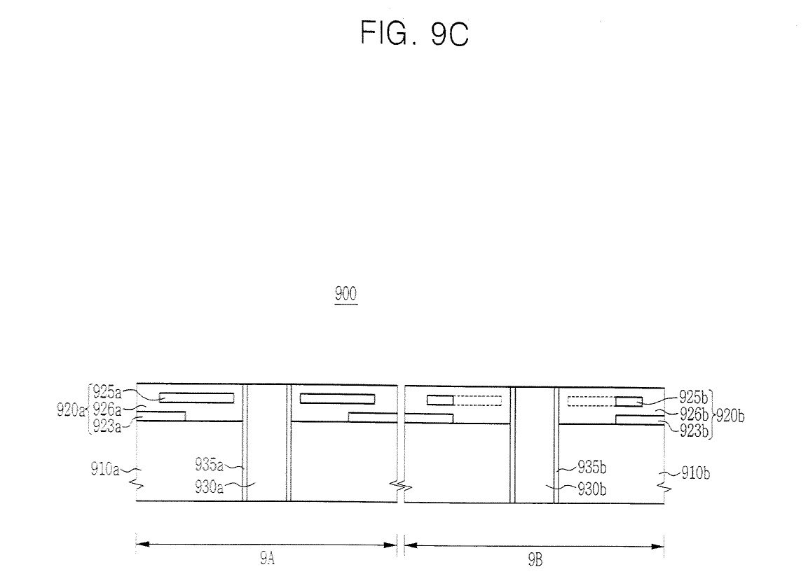

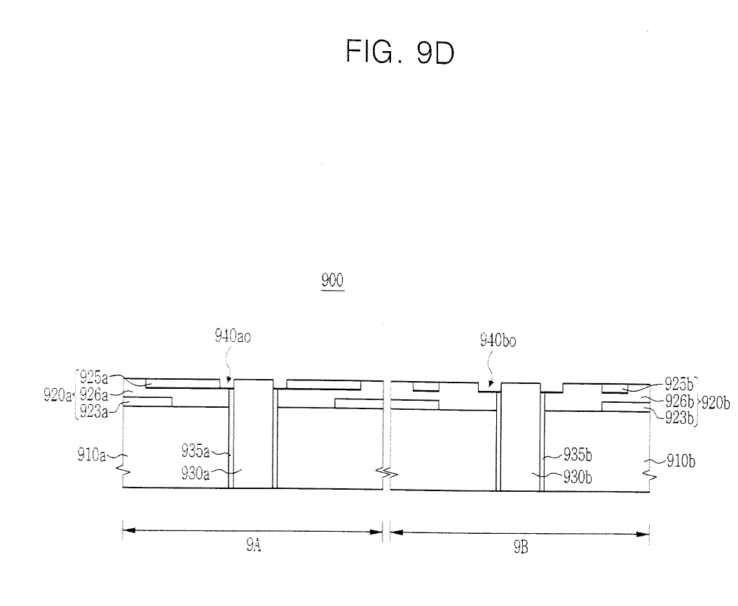

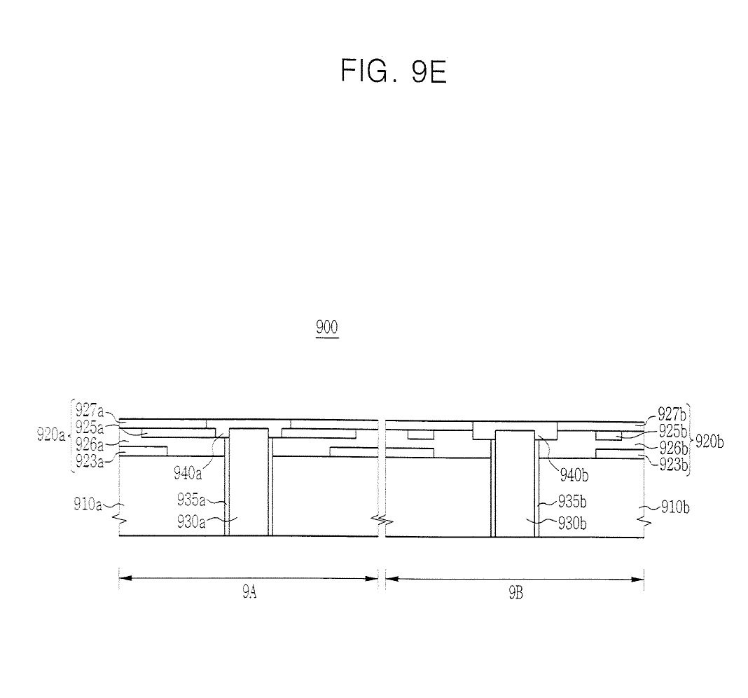

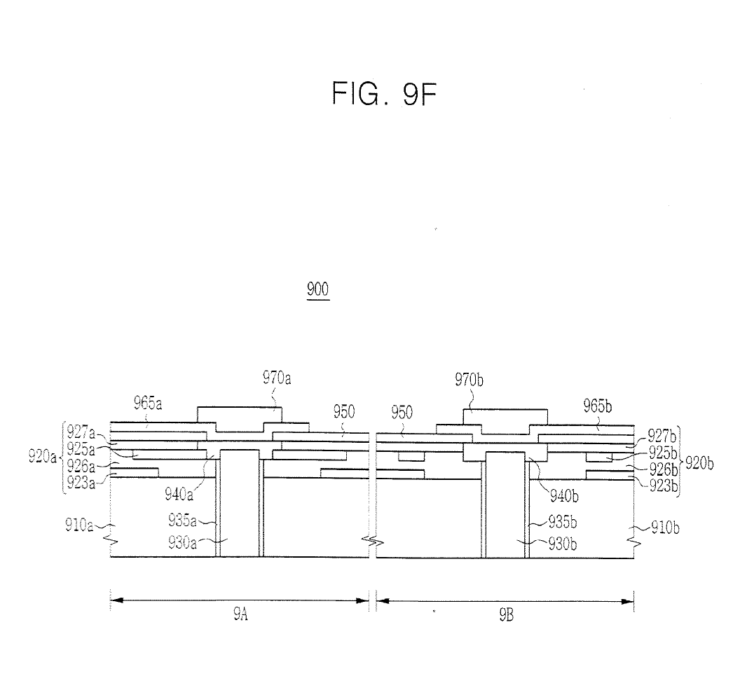

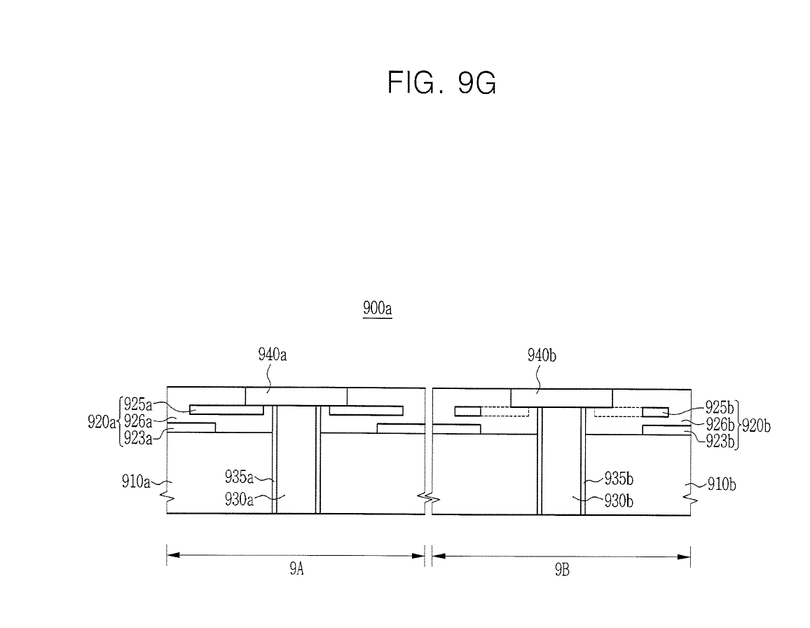

FIGS. 9A to 9G are schematic cross-sectional views illustrating a method of fabricating a semiconductor device 900 according to example embodiments of the present general inventive concept. Referring to FIG. 9A, the semiconductor device 900 including a first region 9A and a second region 9B can be prepared. The regions 9A and 9B may include a first and a second circuitry layers 910a and 910b and a first and a second metal interconnection layers 920a and 920b. The metal interconnection layers 920a and 920b may include multilayer metal interconnections 923 and 925 and a first protection layers 926a, and 926b. In FIG. 9A, two-layer metal interconnections 923a, 923b, 925a, and 925b are illustrated.

Referring to FIG. 9B, TSVPs 930a and 930b can be formed. In the TSVPs 930a and 930b, through silicon via holes may be formed, barrier metal films 935a and 935b may be formed, and via plugs 930a and 930b may be formed. The method of forming the through silicon via holes, the method of forming the barrier metal films 935a and 935b, and the method of forming the TSVPs 930a and 930b are described in detail above in connection with the preceding figures.

Referring to FIG. 9C, the uppermost metal interconnections 925b may be partially removed using a laser cutting method, an ion beam method, or an electronic beam method. When such methods are carried out, surfaces of the uppermost metal interconnections 925b may be exposed. That is, the first protection layer 926b may not cover the uppermost metal interconnections 925b as a whole. However, in the uppermost metal interconnections 925b may be partially removed by controlling a location where a focus is placed without causing significant damage to the first protection layer 926b. Since the first protection layer 926b is an insulating material, it does not have an effect on the operation of a semiconductor device unless otherwise it is significantly damaged. As illustrated in FIG. 9C, the uppermost metal interconnections can be removed, as represented in a dotted line.

Referring to FIG. 9D, openings 940ao and 940bo to form the via pads can be formed. At least a part of top surfaces of the uppermost metal interconnections 925a and 925b of the region 9A may be exposed. Although FIG. 9D illustrates that the top surfaces of the uppermost metal interconnections 925a and 925b are exposed, it is not necessary to do so. For example, in the top surfaces of the uppermost metal interconnections 925a and 925b, portions where the openings 940ao and 940bo can be formed may be exposed, and the other portions may be covered with the first protection layer 926.

Referring to FIG. 9E, via pads 940a and 940b can be formed. Here, a second protection layers 927a and 927b having the same top surface height as top surfaces of the via pads 940a and 940b may be formed. A CMP process may also be performed.

Referring to FIG. 9F, a passivation layer 950, openings exposing top surfaces of the via pads 940a and 940b, and redistribution structures 965a and 965b can be formed. The passivation layer 950 may be formed on at least a portion of or the entire surface of the substrate, and may be formed of at least one of silicon oxide, silicon nitride, silicon oxynitride and one or more polyimides. The openings may be formed, for example, through photolithography. The redistribution structures 965a and 965b may be formed by extending from the top surfaces of the exposed via pads 940a and 940b, sidewalls of the openings, and the top surface of the passivation layer 950. The redistribution structures 965a and 965b may longitudinally extend in a horizontal direction to be electrically or physically connected to other via pads. IO pins 970a and 970b can be formed on the redistribution structures 965a and 965b to fill the openings, so that the semiconductor device according to yet another example embodiment is fabricated.

FIG. 9G illustrates that the semiconductor device 900a according to example embodiments of the present general inventive concept may be formed by in the process of fabricating the semiconductor device 900. Comparing FIG. 9G to FIGS. 9B and 9C, when via pads 940a and 940b are formed, uppermost metal interconnections 925b can be cut. The uppermost metal interconnections 925b may be cut, and the processing of the semiconductor device 900a may proceed with the processes illustrated in FIG. 9E.

A laser cutting method may include irradiating a laser beam onto a metal interconnection to remove the metal interconnection. The laser beam may be irradiated so as to partially remove the metal interconnection without destroying and/or minimizing the destruction of compositions of the protection layers. That is, the laser beam may irradiate the metal interconnection for a duration that is less than the thermal diffusivity of the protection layers. A laser beam may be irradiated from a laser in a pulse wave form. In general, a thermal diffusion time of a silicon compound used as the protection layer is several milliseconds per 1 μm. Therefore, when a laser is irradiated shorter than the thermal diffusion time, the metal interconnection may be removed without having an effect on its compositions.

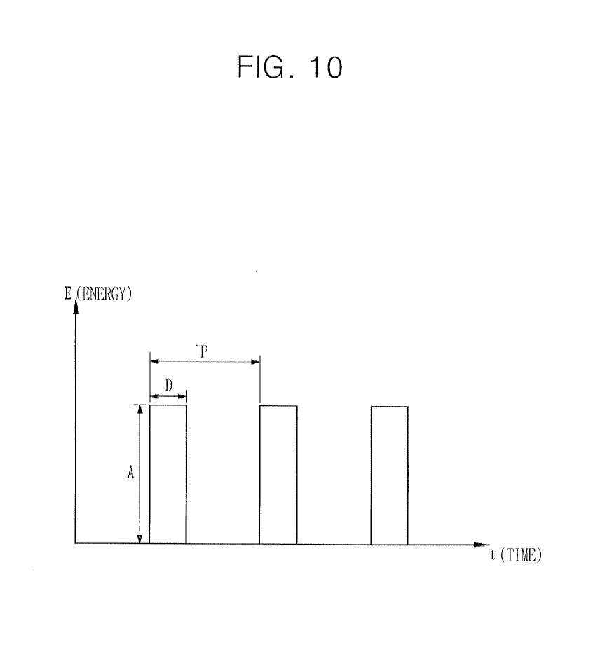

FIG. 10 illustrates a laser beam irradiated from a laser in a laser cutting method applied to semiconductor devices of example embodiments of the present general inventive concept. Referring to FIG. 10, for example, a laser beam with an energy (A), a pulse duration (D), a pulse pitch (P) and a frequency (F) is irradiated from a laser. That is, the irradiated laser beam may form various stress generators by adjusting the energy (A), the pulse duration (D) and the frequency. A pitch of each pulse may be determined depending on the frequency (F). For example, the pulse duration (D) may be set to less than a half of the pitch.

A laser used in the example embodiments may use Ti:Sapphire as a light source. In particular, irradiation time may be controlled in units of femptoseconds.

The laser in the example embodiments may irradiate a beam with an energy (A) of several μJ (micro Joules) per pulse, a pulse duration (D) of several ps (picoseconds), and a frequency of 100 KHz (kiloHertz). These beam characteristics are exemplary, and the present general inventive concept is not limited thereto. For example, while a pulse energy (A) of μJ level can be used in example embodiments of the present general inventive concept, a high-energy pulse of mJ (milliJoules) level may be used or a laser with a lower pulse energy (e.g., picoJoule pulses) may be used. The pulse duration (D) of the laser beam may be smaller than that of a femtosecond time scale. The beam characteristics may be selected according to compositions and size of a protection layer and a metal interconnection, and thus the present example embodiments, and well as the spirit and scope of the example embodiments of the present general inventive concept, are not limited thereto.

Each process variable of the exemplary embodiments of the present general inventive concept may include more sensitive elements and less sensitive elements. Further, depending on the fabrication equipment, the kind of a laser, density of a laser beam, and a profile of a laser beam, parts in which stress occurs may appear in one or more locations. Therefore, numerical values provided in the specification are merely exemplary, and should not be construed as limiting.

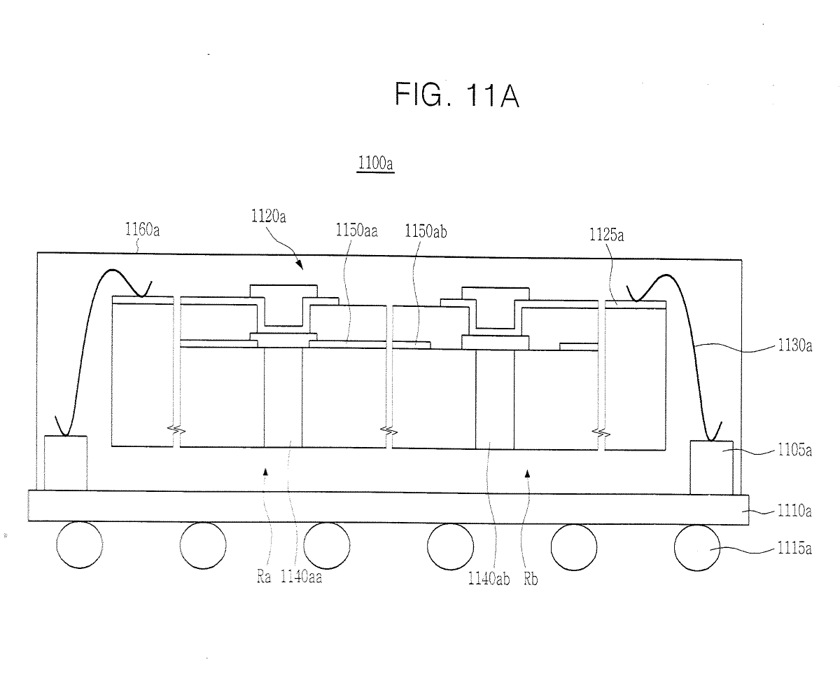

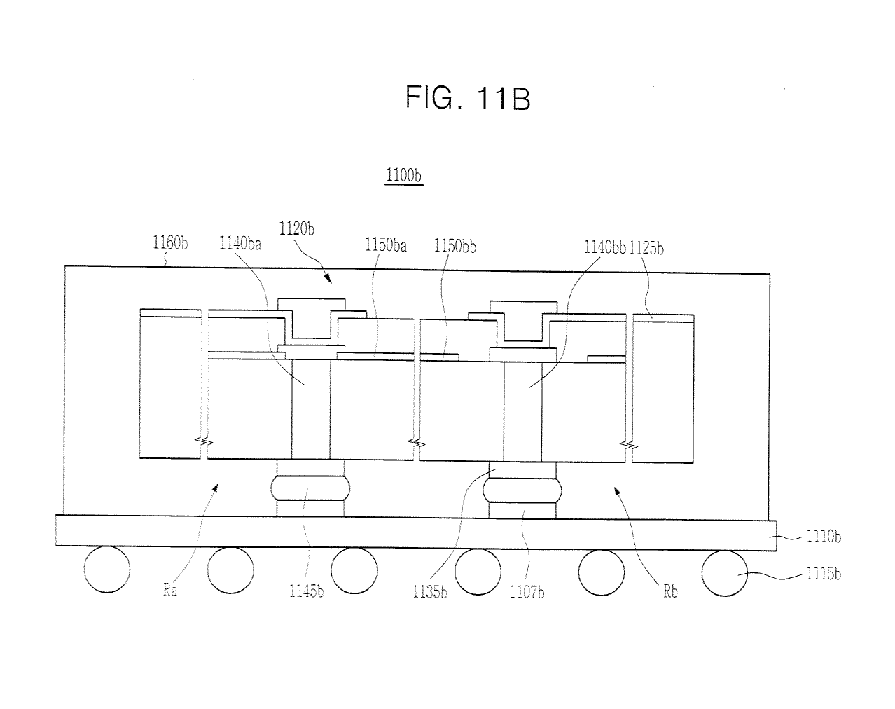

FIGS. 11A and 11B illustrate schematic cross-sectional views of semiconductor packages including a semiconductor device according to example embodiments of the present general inventive concept. Referring to FIG. 11A, a semiconductor package 1100a according to example embodiments of the present general inventive concept includes a package substrate 1110a having wire pads 1105a and substrate connectors 1115a, a semiconductor device 1120a having bonding pads 1125a disposed on the package substrate 1110a, and wires 1130a to electrically connect the wire pads 1105a to the bonding pads 1125a, respectively. FIG. 11B includes bonding pad 1125b. The semiconductor device 1120a may be any one of the semiconductor devices described in the specification and illustrated is FIGS. 1A to 4B.

The semiconductor device 1120a may include a first region Ra and a second region Rb. The region Ra may includes a first TSVP 1140aa and a first metal interconnection 1150aa electrically connected to the first TSVP 1140aa. The region Rb may include a second TSVP 1140ab and a second metal interconnection 1150ab electrically insulated from the second TSVP 1140ab. The first metal interconnection 1150aa and the second metal interconnection 1150ab may be formed at or about the same level.

The semiconductor device 1120a may be covered by a package lid 1160a. Spaces between the semiconductor device 1120a and the package substrate 1110a and between the semiconductor device 1120a and the package lid 1160a may be filled with fillers, respectively.

Referring to FIG. 11B, a semiconductor package 1110b according to example embodiments of the present general inventive concept includes a package substrate 1110b having solder lands 1107b and substrate connectors 1115b, a semiconductor device 1120b having solder pads 1135b disposed on the package substrate 1110b, solders 1145b to electrically connect the solder lands 1107b to the solder pads 1135b, respectively. The solders 1145 may be named not by material, but by function. The solders may be understood as metal connectors. The semiconductor 1120b may be any one of the semiconductor devices described in the specification and illustrated is FIGS. 1A to 4B.

The semiconductor device 1120b may include a first region Ra and a second region Rb. The region Ra may includes a first TSVP 1140ba and a first metal interconnection 1150ba electrically connected to the first TSVP 1140ba. The region Rb may includes a second TSVP 1140bb and a second metal interconnection 1150bb electrically insulated from the second TSVP 1140bb. The first metal interconnection 1150ba and the second metal interconnection 1150bb may be formed at or about the same level. The first TSVP 1140ba may be electrically connected to the solder pad 1135b located at the first region Ra. The second TSVP 1140bb may be electrically connected to the solder pad 1135b located at the second region Rb.

The semiconductor device 1120b may be covered by a package lid 1160b. Spaces between the semiconductor device 1120b and the package substrate 1110b and between the semiconductor device 1120b and the package lid 1160b may be filled with fillers, respectively.

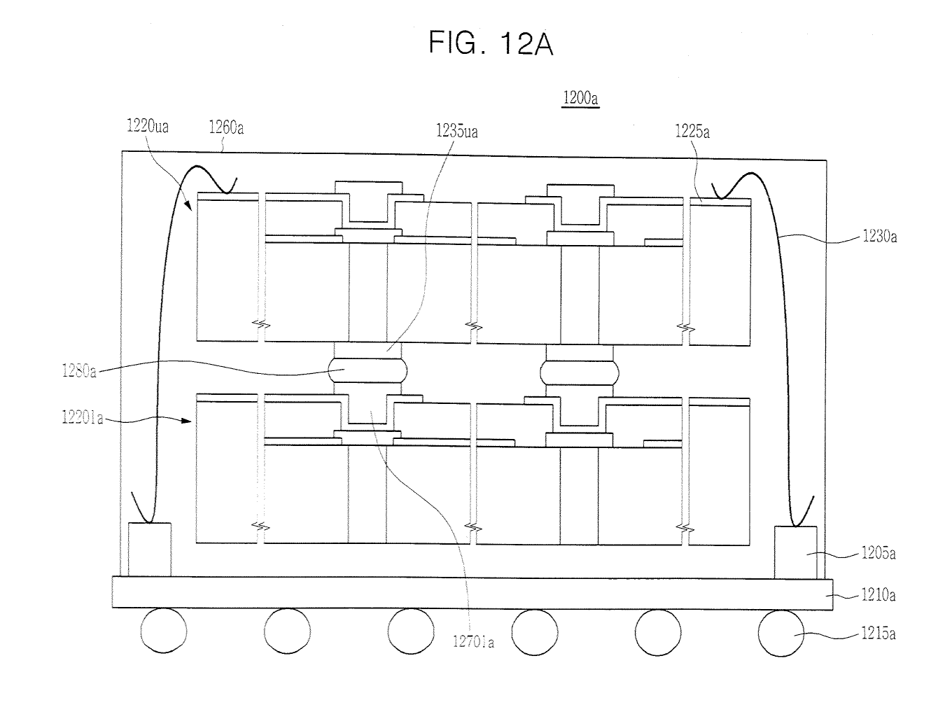

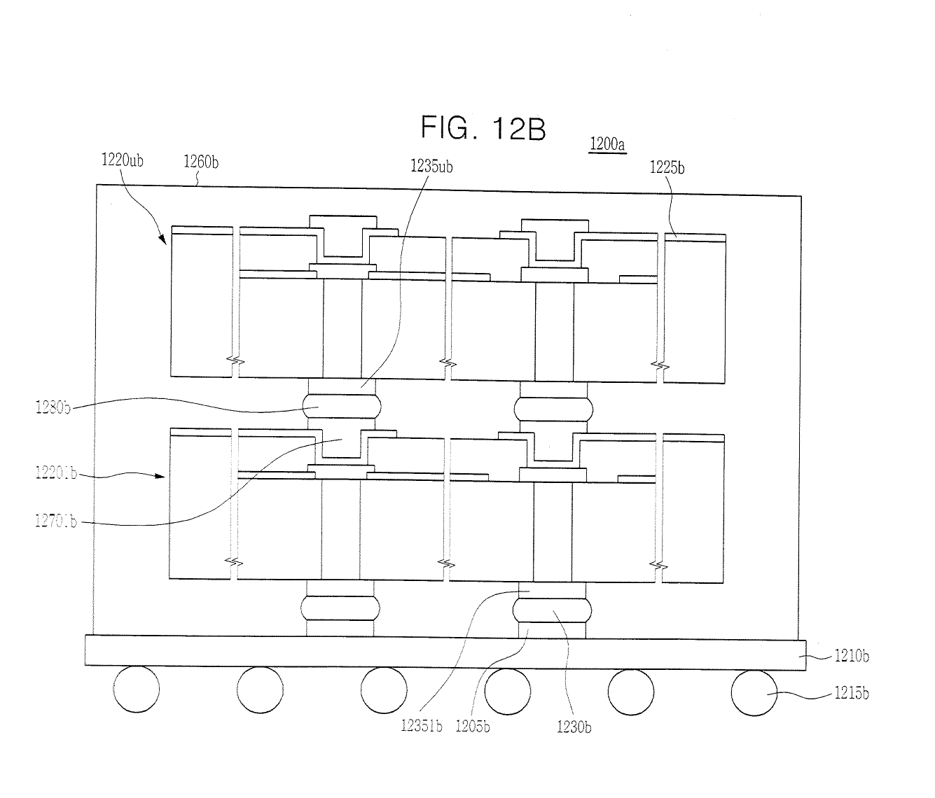

FIGS. 12A and 12B are schematic cross-sectional views of semiconductor packages 1200a and 1200b including a semiconductor device according to various example embodiments of the present general inventive concept. Referring to FIG. 12A, a semiconductor package 1200a according to example embodiments of the present general inventive concept includes a package lid 1260a, a package substrate 1210a having wire pads 1205a and substrate connectors 1215a, a lower semiconductor device 12201a and a upper semiconductor device 1220ua stacked on the lower semiconductor device 12201a. The lower semiconductor device 12201a may be electrically connected to the upper semiconductor device 1220ua through at least one of IO pins 12351a on the lower semiconductor device 12201a, at least one of solder pads 1235ua beneath the upper semiconductor device 1220ua, and at least one of solders (or connectors) 1280a formed between solder pad 1235ua and solder land 12701a. At least one of the semiconductor devices 1220ua and 12201a may be any one of the semiconductor devices described in the specification and illustrated is FIGS. 1A to 4B. The wire pad 1205a may be electrically connected to the upper semiconductor device 1220ua via wire 1230a to a bonding pad 1225a.

Referring to FIG. 12B, a semiconductor package 1200b according to example embodiments of the present general inventive concept includes a package substrate 1210b having solder lands 1205b, bonding pad 1225b, solder 1230b, and substrate connectors 1215b, a lower semiconductor device 12201b, an upper semiconductor device 1220ub stacked on the lower semiconductor device 1220lb, and a package lid 1260b disposed on the package substrate 1210b. The lower semiconductor device 1220lb may be electrically connected to the upper semiconductor device 1220ub through the solder land 1270lb, at least one of IO pins 1235lb on the lower semiconductor device 1220lb, at least one of solder pads 1235ub beneath the upper semiconductor device 1220ub, and at least one of solders (or connectors) 1280b. At least one of the semiconductor devices 1220ub and 1220lb may be any one of the semiconductor devices described in the specification and illustrated in FIGS. 1A to 4B.

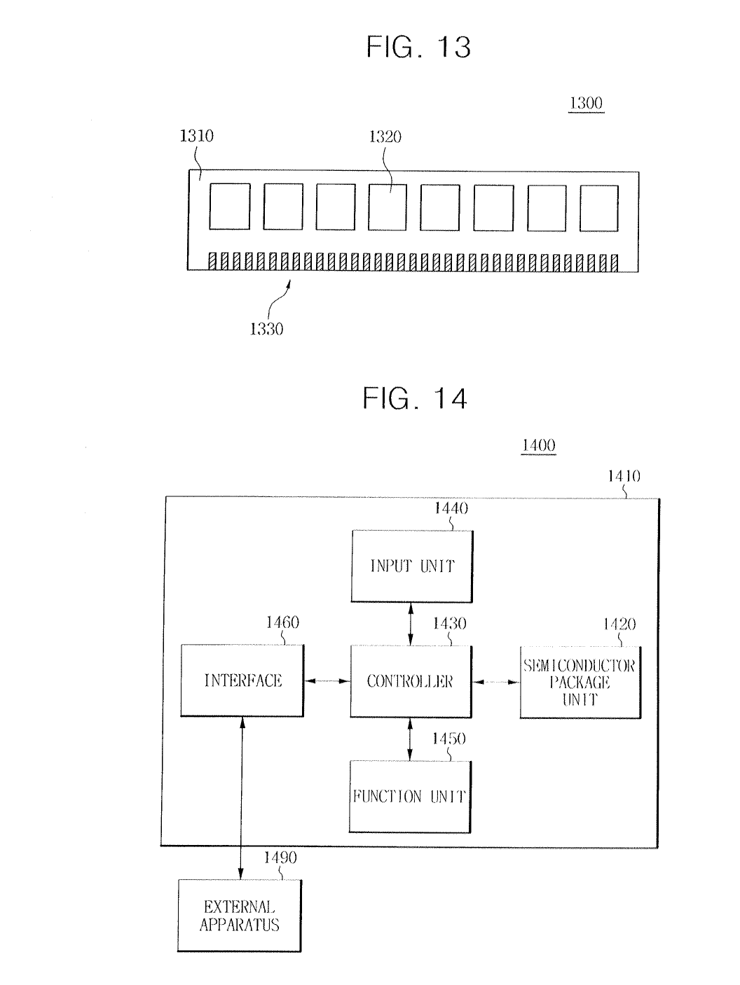

FIG. 13 is a plan view illustrating a semiconductor module including a semiconductor device according 3120 to example embodiments of the present general inventive concept. Referring to FIG. 13, a semiconductor module 1300 according to exemplary embodiments of the present general inventive concept includes a module substrate 1310, a plurality of semiconductor devices 1320 disposed on the module substrate 1310, and a plurality of contact terminals 1330 formed at an edge of the module substrate 1310 and connected to the plurality of semiconductor devices 1320, respectively. The module substrate 1310 may be a printed circuit board. Both sides of the module substrate 1310 may be used. In other words, the semiconductor devices may be disposed on both sides of the module substrate 1310. One of the semiconductor devices 1320 may be a control device to control the other semiconductor devices 1320. Or, another semiconductor device to control the plurality of semiconductor devices 1320 may be further disposed. At least one of the semiconductor devices 1320 may include at least one of the semiconductor devices according to exemplary embodiments of the present general inventive concept. The contact terminals 1330 may be formed of metals. The contact terminals 1330 may be variously formed and/or disposed on the module substrate. Thus, a predetermined number of the contact terminals 1330 may be selected, and is not limited to the number illustrated in FIG. 13. The semiconductor devices 1320 may be interpreted as the semiconductor packages according to exemplary embodiments of the present general inventive concept.

FIG. 14 is a block diagram illustrating an electronic apparatus including a semiconductor device according to various example embodiments of the present general inventive concept. FIG. 14 is a block diagram illustrating an electronic apparatus 1400 according to an embodiment of the present general inventive concept. The electronic apparatus 1400 may include a housing 1410 to accommodate elements or units of the electronic apparatus 1400, a memory unit 1420, a controller 1430, an input/output unit 1440, a function unit 1450, and/or an interface unit 1460 to communicate with an external apparatus 1490 through a wired or wireless communication line to receive and transmit data or signals. At least one of the semiconductor devices and/or the semiconductor module can be used as the memory unit 1420. Therefore, the memory unit 1420 can be referred to as the semiconductor devices or the semiconductor module. The data may be input through the input/output unit 1440, the function unit 1450, and/or the external apparatus 1490 through the interface unit 1460. The function unit 1450 may be a unit to perform a function or operation of the electronic apparatus 1400. For example, when the electronic apparatus 1400 is an image processing apparatus, a television apparatus, or a monitor apparatus, the function unit 1450 may be a display unit to display an image and/or an audio output unit to generate a signal or sound according to the data. When the electronic apparatus is a mobile phone, the function unit 1450 may be a mobile phone function unit to perform a mobile phone function, for example, dialing, text messaging, photographing using a camera unit formed on the housing 1410, audio and video data processing to be displayed on a display unit formed on the housing 1410, etc. When the electronic apparatus is an image forming or scanning apparatus, the function unit 1450 may be an image forming unit to feed a printing medium, to form or print an image on the printing medium, or to scan a document or picture to be stored in the memory unit. When the electronic apparatus 1400 is a camera or camcorder, the function unit 1450 may be a unit to photograph an image as a movie or a still image. The controller 1430 may control elements and units of the electronic apparatus 1400 or may be a processor. At least one of the semiconductor devices and the semiconductor module can be included in the controller 1430. Therefore, the controller 1430 can be referred to as the semiconductor devices or the semiconductor module.

As described above, a semiconductor device and a stacked structure of the semiconductor device according to the inventive concept enable an insulating problem between patterns caused when copper is used to be overcome, so that stable operation can be implemented. Further, a method of fabricating the semiconductor device according to example embodiments of the present general inventive concept enables the insulating problems between patterns at a desired place to be minimized and/or overcome, even though a circuit standard or design of the semiconductor device is changed, so that productivity can be enhanced.

The foregoing is illustrative of example embodiments and is not to be construed as limiting thereof. Although a several example embodiments have been described, those skilled in the art will readily appreciate that many modifications are possible in example embodiments without materially departing from the novel teachings and advantages. Accordingly, all such modifications are intended to be included within the scope of this present general inventive concept as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

1. A semiconductor device comprising:
a semiconductor device having a metal interconnection layer on a circuit layer having a copper interconnection, and first and second via pads; and
wherein the first via pad is electrically connected to the copper interconnection, and the second via pad is electrically insulated from the copper interconnection.

2. The semiconductor device of claim 1, further comprising:
a first and a second through silicon via plugs, wherein the first and second via pads are disposed on the first and second through silicon via plugs, respectively.

3. The semiconductor device of claim 2, wherein the first through silicon via plug is electrically connected to the first via pad to transfer a voltage.

4. The semiconductor device of claim 2, wherein the second through silicon via plug is electrically connected to the second via pad to transfer a chip select signal.

5. The semiconductor device of claim 2, wherein the first via pad and the second via pad are formed of copper.

6. The semiconductor device of claim 1, further comprising:
a solder pad beneath surfaces of the first through silicon via plug and the circuit layer.

7. The semiconductor device of claim 1, wherein the metal interconnection layer further includes a protection layer, the protection layer being directly in contact with the metal interconnection layer.

8. The semiconductor device of claim 1, wherein the first and second through silicon via plugs vertically penetrate the circuit layer.

9. The semiconductor device of claim 1, further comprising:
a first redistribution structure on the circuit layer being electrically connected to the first via pad.

10. The semiconductor device of claim 9, further comprising:
a first bonding pad on the first redistribution structure.

11. The semiconductor device of claim 9, further comprising:
a second redistribution structure on the circuit layer being electrically connected to the second via pad.

12. The semiconductor device of claim 11, further comprising:
a second bonding pad on the second redistribution structure.

13. A semiconductor package comprising:
a package substrate having a wire pad;
a semiconductor device disposed on the package substrate, the semiconductor device having a metal interconnection layer having a copper interconnection, and first and second via pads on a circuit layer; and
wherein the first via pad is electrically connected to the copper interconnection, and the second via pad is electrically insulated from the copper interconnection.

14. The semiconductor package of claim 13, wherein the semiconductor device further comprising:
a redistribution structure on the circuit layer being electrically connected to the first via pad; and
a bonding pad on the first redistribution structure.

15. The semiconductor package of claim 14, further comprising:
a wire pad on the package substrate being electrically connected to the bonding pad.

16. The semiconductor package of claim 13, further comprising:
a lower semiconductor device between the package substrate and the semiconductor device,
wherein the lower semiconductor device comprises:
a lower metal interconnection layer on a lower circuit layer having a lower copper interconnection, and third and fourth via pads; and
wherein the third via pad is electrically connected to the lower copper interconnection, and
wherein the fourth via pad is electrically insulated to the lower copper interconnection.

17. The semiconductor package of claim 16, wherein the first through silicon via plug is electrically connected to the third through silicon via plug.

18. The semiconductor package of claim 17, wherein the second through silicon via plug is electrically connected to the fourth through silicon via plug.

19. A semiconductor package comprising:
a package substrate having a solder land;
a semiconductor device disposed on the package substrate, the semiconductor device having a solder pad; and
a connector to electrically connect the solder land to the solder pad,
wherein the semiconductor device comprises,
a circuit layer on a substrate;
a metal interconnection layer on the circuit layer, the metal interconnection layer having a copper interconnection and a protection layer;
a first and a second through silicon via plugs vertically penetrating the circuit layer;
a first via pad on the first through silicon via plug; and
a second via pad on the second through silicon via plug,
wherein the first via pad is electrically connected to the copper interconnection, and
wherein the second via pad is electrically insulated to the copper interconnection, and wherein the solder pad is electrically connected to the first through silicon via plug.

20. The semiconductor package of claim 19, further comprising:
an upper semiconductor device disposed on the semiconductor device, wherein the upper semiconductor device comprises,
an upper circuit layer on an upper substrate,
an upper metal interconnection layer on the upper circuit layer, the upper metal interconnection layer including an upper copper interconnection and an upper protection layer;
a third and a fourth through silicon via plug vertically penetrating the upper circuit layer;
a third via pad on the third through silicon via plug; and
a fourth via pad on the fourth through silicon via plug,
wherein the third via pad is electrically connected to the upper copper interconnection,
wherein the fourth via pad is electrically insulated to the upper copper interconnection, and
wherein the first through silicon via plug is electrically connected to the third through silicon via plug.

21.-31. (canceled)
